(19) United States
(12) Patent Application Publication
(10) Pub. No.: US 2026/0074162 A1
(43) Pub. Date: Mar. 12, 2026

(54) PLASMA PROCESSING METHOD AND PLASMA PROCESSING APPARATUS

(71) Applicant: Tokyo Electron Limited, Tokyo (JP)

(72) Inventor: Chishio KOSHIMIZU, Miyagi (JP)

(73) Assignee: Tokyo Electron Limited, Tokyo (JP)

(21) Appl. No.: 19/392,178

(22) Filed: Nov. 18, 2025

Related U.S. Application Data
(63) Continuation of application No. PCT/JP2024/017927, filed on May 15, 2024.

(30) Foreign Application Priority Data
May 25, 2023 (JP) 2023-086375

(51) Int. Cl. H01J 37/32

(52) U.S. Cl. CPC H01J 37/32697; H01J 37/32183; H01J 37/32715; H01J 2237/334

(57) ABSTRACT

A plasma processing method for performing plasma processing on a substrate, the method including: acquiring, for each control period of a bias signal, a parameter relating to an impedance matching state when supplying the bias signal to an electrode provided at a substrate support; and determining a frequency f(n) of the bias signal in an n-th control period according to Equation (1) below, f(n)=f(n−1)−Δf/ΔP×Pr(n−1)×F . . . (1).

### CROSS-REFERENCE TO RELATED APPLICATIONS

This application is a bypass continuation application of international application No. PCT/JP2024/017927 having an international filing date of May 15, 2024 and designating the United States, the international application being based upon and claiming the benefit of priority from Japanese Patent Application No. 2023-086375, filed on May 25, 2023, the entire contents of each are incorporated herein by reference.

### TECHNICAL FIELD

The present disclosure relates to a plasma processing method and a plasma processing apparatus.

### BACKGROUND

PTL 1 discloses a method of applying a plasma excitation radio-frequency pulse to a plasma source, which is a frequency control method of shifting the frequency of the radio-frequency pulse to a frequency relatively higher than the frequency in a steady state in which pulsed plasma is excited at the time of plasma ignition.

### CITATION LIST

### Patent Documents

PTL 1: JPH10-064696

### SUMMARY

The technique of the present disclosure optimizes conditions for supplying RF power at the time of plasma ignition.

An aspect of the present disclosure is a plasma processing method for performing plasma processing on a substrate, the method including: acquiring, for each control period of a bias signal, a parameter relating to an impedance matching state when supplying the bias signal to an electrode provided at a substrate support; and determining a frequency f(n) of the bias signal in an n-th control period according to Equation (1) below,

f(n)=f(n−1)−Δf/ΔP×Pr(n−1)×F . . . (1),

Δf=f(n−2)−f(n−1),

ΔP=Pr(n−2)−Pr(n−1),
f(n−2) being a frequency in an (n−2)-th control period, f(n−1) being a frequency in an (n−1)-th control period, Pr(n−2) being the parameter in the (n−2)-th control period, Pr(n−1) being the parameter in the (n−1)-th control period, n being an integer of 3 or more, and F being a constant.

According to the present disclosure, conditions for supplying RF power at the time of plasma ignition can be optimized.

### BRIEF DESCRIPTION OF DRAWINGS

The scope of the present disclosure is best understood from the following detailed description of exemplary embodiments when read in conjunction with the accompanying drawings.

FIG. 1 is a diagram illustrating a configuration example of a plasma processing system according to one embodiment.

FIG. 2 is a cross-sectional view illustrating the configuration example of the plasma processing apparatus according to one embodiment.

FIG. 3 is a flowchart illustrating an example of a plasma processing method according to one embodiment.

FIG. 4 is a flowchart illustrating an outline of a bias signal supply method according to a first embodiment.

FIG. 5 is a graph illustrating behaviors of a bias signal, a bias frequency, and reflected wave power in the bias signal supply method according to the first embodiment.

FIG. 6 is a flowchart illustrating an outline of a method of determining a bias frequency in the bias signal supply method according to the first embodiment.

FIG. 7 is a flowchart illustrating an outline of a bias signal supply method according to a second embodiment.

FIG. 8 is a graph illustrating behaviors of a bias signal, a bias frequency, and reflected wave power in the bias signal supply method according to the second embodiment.

FIG. 9 is a flowchart illustrating an outline of a method of determining a bias frequency in the bias signal supply method according to the second embodiment.

FIG. 10 is a flowchart illustrating an outline of a bias signal supply method according to a third embodiment.

FIG. 11 is a flowchart illustrating an outline of a method of determining a bias frequency in the bias signal supply method according to the third embodiment.

FIG. 12 is a flowchart illustrating an outline of a source signal supply method according to a fourth embodiment.

FIG. 13 is a flowchart illustrating an outline of a method of determining a steady matcher position in the source signal supply method according to the fourth embodiment.

FIG. 14 is a flowchart illustrating an outline of sweeping of a source frequency at the steady matcher position in the source signal supply method according to the fourth embodiment.

FIG. 15 is a flowchart illustrating an example of bias signal control in the source signal supply method according to the fourth embodiment.

FIG. 16 is a graph illustrating reflected wave power or emission intensity at the time of plasma ignition in the source signal supply method according to the fourth embodiment.

FIG. 17 is a flowchart illustrating another example of the bias signal control in the source signal supply method according to the fourth embodiment.

FIG. 18 is a graph illustrating reflected wave power or emission intensity at the time of plasma ignition in the source signal supply method according to the fourth embodiment.

FIG. 19 is a flowchart illustrating still another example of the bias signal control in the source signal supply method according to the fourth embodiment.

FIG. 20 is a flowchart illustrating an example of source signal control in the source signal supply method according to the fourth embodiment.

FIG. 21 is a flowchart illustrating an example of matcher position control in the source signal supply method according to the fourth embodiment.

### DETAILED DESCRIPTION

In a process of manufacturing a semiconductor device, a processing module accommodating a semiconductor wafer (hereinafter referred to as a “substrate”) is brought into a pressure-reduced state, and various processing steps of performing predetermined processing are performed on the substrate. The processing steps are performed using, for example, a substrate processing apparatus in which processing modules are disposed around a common transfer module.

Examples of the substrate processing apparatus include a plasma processing apparatus as disclosed in PTL 1. In a parallel plate type plasma processing apparatus as an example of the plasma processing apparatus, a substrate is introduced into an airtight plasma processing space that includes an upper electrode and a lower electrode, and plasma is generated with a desired gas type and a gas pressure. Subsequently, ions in the generated plasma are attracted to the substrate to perform plasma processing such as etching on the substrate. The generation of plasma and the attraction of plasma ions to the substrate are performed by supplying a source signal and/or a bias signal, which is RF power (radio-frequency power), to the upper electrode and/or the lower electrode.

When the RF power is applied to the upper electrode and/or the lower electrode, plasma is generated. However, at the time of plasma ignition, when a density of molecules entering a plasma state from a non-plasma state increases (hereinafter referred to as plasma growth), an impedance changes along with the plasma growth. When an impedance mismatch occurs between an RF power source and the plasma processing space due to the change in impedance, reflected waves of the RF power are generated from the plasma processing space. When power of the reflected waves exceeds reflected wave durability of the RF power source, disadvantages may occur such as damage to the RF power source or requirement for time for the generated plasma to stabilize. In the related art, a matching circuit configured to match the impedances of the RF power source and the plasma processing space is provided. However, in the matching circuit in the related art, matching cannot be performed, and large reflection is likely to occur. The reason for this is that in the matching circuit in the related art, control of the order of seconds by changing a position of the matcher using a motor is necessary, and it is not possible to follow an impedance change of the order of microseconds or less.

Further, as disclosed in PTL 1, a technique has been proposed in which a pulsed plasma is excited by applying a pulse of RF power with on/off control or high/low control to the upper electrode and/or the lower electrode so as to process the substrate. When the pulse frequency is high (an on/off interval or a high/low interval is short), the number of times of plasma ignition increases, and a total sum of the reflected wave power at the time of plasma ignition increases. The present inventors have found that various problems such as a decrease in power efficiency and an increase in load on the RF power source occur along with an increase in the total sum of the reflected wave power.

Further, the total sum of the reflected wave power increases as the time until the impedances match and the plasma is ignited increases. The present inventors have found that it is possible to reduce the total sum of the reflected wave power by reducing the time required for the plasma to be ignited together with the reduction of the reflected wave power.

Therefore, the technique according to the present disclosure optimizes conditions for supplying the RF power at the time of plasma ignition. Specifically, the reflected wave power is reduced by optimizing the supply of the bias signal, and the time to plasma ignition is shortened by optimizing the supply of the source signal.

Hereinafter, a plasma processing system according to an embodiment will be described with reference to the drawings. The same reference numerals will be given to elements having substantially the same functional configurations throughout the specification, and redundant description thereof have been omitted.

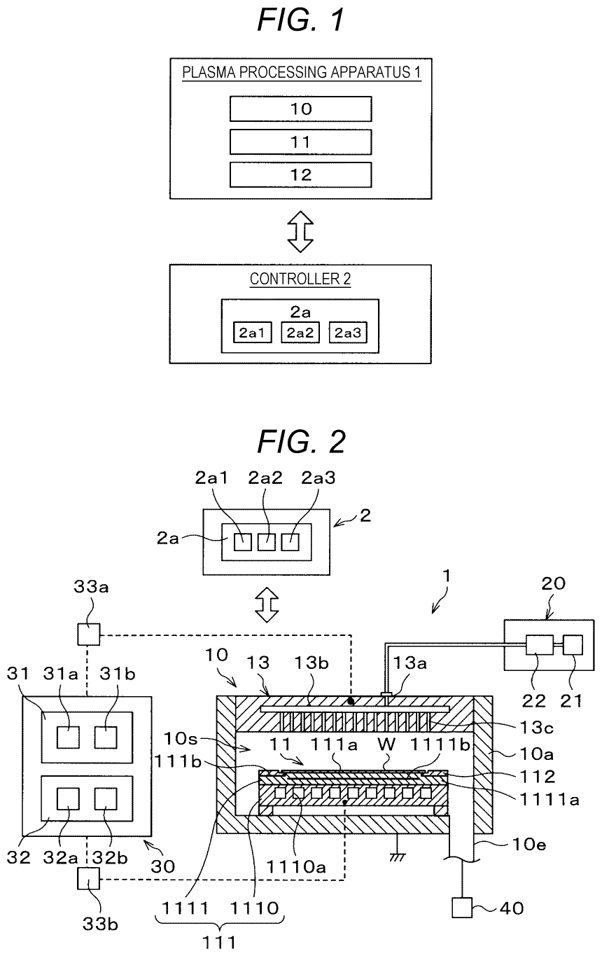

FIG. 1 is a diagram illustrating an example of a configuration of a plasma processing system. In one embodiment, the plasma processing system includes a plasma processing apparatus 1 and a controller 2 (herein controller means the same as controller circuitry). The plasma processing apparatus 1 includes a plasma processing chamber 10, a substrate support 11, and a plasma generator 12. The plasma processing chamber 10 has a plasma processing space. The plasma processing chamber 10 has at least one gas supply port via which at least one processing gas is supplied into the plasma processing space, and at least one gas exhaust port via which the gas is exhausted from the plasma processing space. The gas supply port is connected to a gas supply 20, which will be described later, and the gas exhaust port is connected to an exhaust system 40, which will be described later. The substrate support 11 is disposed in the plasma processing space and has a substrate support surface for supporting a substrate.

The plasma generator 12 is configured to generate plasma from at least one processing gas supplied into the plasma processing space. The plasma formed in the plasma processing space may be capacitively coupled plasma (CCP), inductively coupled plasma (ICP), electron-cyclotron-resonance plasma (ECR plasma), helicon wave plasma (HWP), surface wave plasma (SWP), or the like. Further, various types of plasma generators, including an alternating current (AC) plasma generator and a direct current (DC) plasma generator, may be used. In one embodiment, an AC signal (AC power) used by the AC plasma generator has a frequency in a range of 100 kHz to 10 GHz. Accordingly, the AC signal includes a radio frequency (RF) signal and a microwave signal. In one embodiment, the RF signal has a frequency in a range of 100 kHz to 150 MHz.

The controller 2 processes computer-executable instructions for instructing the plasma processing apparatus 1 to execute various steps described herein below. The controller 2 may be configured to control elements of the plasma processing apparatus 1 to execute the various steps described herein below. In one embodiment, part or all of the controller 2 may be in the plasma processing apparatus 1. The controller 2 may include a processor 2a1, a storage 2a2, and a communication interface 2a3. The controller 2 is implemented, for example, by a computer 2a. The processor 2a1 may be configured to read a program from the storage 2a2 and perform various control operations by executing the read program. The program may be stored in advance in the storage 2a2, or may be acquired via a medium when necessary. The acquired program is stored in the storage 2a2, read from the storage 2a2 by the processor 2a1, and executed thereby. The medium may be any of various recording media readable by the computer 2a, or may be a communication line connected to the communication interface 2a3. The processor 2a1 may be a central processing unit (CPU). The storage 2a2 may include a random access memory (RAM), a read only memory (ROM), a hard disk drive (HDD), a solid state drive (SSD), or a combination thereof. The communication interface 2a3 may communicate with the plasma processing apparatus 1 via a communication line such as a local area network (LAN). The controller circuitry can be programmable circuitry (e.g., embedded processor) or fixed circuitry (e.g., ASIC or PAL). In an exemplary embodiment, the controller circuitry can include one or more programmable processors/controllers.

Hereinafter, a configuration example of a capacitively-coupled plasma processing apparatus 1 as an example of the plasma processing apparatus 1 will be described. FIG. 2 is a view for explaining an example of a configuration of a capacitively-coupled plasma processing apparatus 1.

The capacitively-coupled plasma processing apparatus 1 includes the plasma processing chamber 10, the gas supply 20, a power source 30, and the exhaust system 40. The plasma processing apparatus 1 further includes the substrate support 11 and a gas introduction unit. The gas introduction unit is configured to introduce at least one processing gas into the plasma processing chamber 10. The gas introduction unit includes a shower head 13. The substrate support 11 is disposed in the plasma processing chamber 10. The shower head 13 is disposed above the substrate support 11. In one embodiment, the shower head 13 constitutes at least a portion of a ceiling of the plasma processing chamber 10. The plasma processing chamber 10 has a plasma processing space 10s defined by the shower head 13, a sidewall 10a of the plasma processing chamber 10, and the substrate support 11. The plasma processing chamber 10 is grounded. The shower head 13 and the substrate support 11 are electrically insulated from the housing of the plasma processing chamber 10.

The substrate support 11 includes a main body 111 and a ring assembly 112. The main body 111 has a central region 111a, which supports a substrate W, and an annular region 111b, which supports the ring assembly 112. A wafer is an example of the substrate W. The annular region 111b of the main body 111 surrounds the central region 111a of the main body 111 in a plan view. The substrate W is disposed on the central region 111a of the main body 111, and the ring assembly 112 is disposed on the annular region 111b of the main body 111 so as to surround the substrate W on the central region 111a of the main body 111. Accordingly, the central region 111a is also called a substrate support surface that supports the substrate W, and the annular region 111b is also called a ring support surface that supports the ring assembly 112.

In one embodiment, the main body 111 includes a base 1110 and an electrostatic chuck 1111. The base 1110 includes a conductive member. The conductive member of the base 1110 may function as a lower electrode. The electrostatic chuck 1111 is disposed on the base 1110. The electrostatic chuck 1111 includes a ceramic member 1111a, and an electrostatic electrode 1111b disposed in the ceramic member 1111a. The ceramic member 1111a has the central region 111a. In one embodiment, the ceramic member 1111a also has the annular region 111b. Another member that surrounds the electrostatic chuck 1111, such as an annular electrostatic chuck and an annular insulating member, may have the annular region 111b. In this case, the ring assembly 112 may be disposed on the annular electrostatic chuck or the annular insulating member, or may be disposed on both the electrostatic chuck 1111 and the annular insulating member. At least one RF/DC electrode coupled to an RF power source 31 and/or a DC power source 32, which will be described later, may be disposed in the ceramic member 1111a. In this case, at least one RF/DC electrode functions as the lower electrode. When a bias signal and/or a DC signal, which will be described later, is supplied to at least one RF/DC electrode, the RF/DC electrode is also referred to as a bias electrode. The conductive member of the base 1110 and at least one RF/DC electrode may function as a plurality of lower electrodes. The electrostatic electrode 1111b may instead function as the lower electrode. The substrate support 11 therefore includes at least one lower electrode.

The ring assembly 112 includes one or more annular members. In one embodiment, the one or more annular members include one or more edge rings and at least one cover ring. The edge ring is made of an electrically conductive material or an insulating material, and the cover ring is made of an insulating material.

Further, the substrate support 11 may include a temperature control module configured to adjust at least one of the electrostatic chuck 1111, the ring assembly 112, and the substrate W to a target temperature. The temperature control module may include a heater, a heat transfer medium, a flow path 1110a, or a combination thereof. A heat transfer fluid, such as brine or gas, flows through the flow path 1110a. In one embodiment, the flow path 1110a is formed in the base 1110, and one or more heaters are disposed in the ceramic member 1111a of the electrostatic chuck 1111. The substrate support 11 may further include a heat transfer gas supply configured to supply a heat transfer gas to a gap between a rear surface of the substrate W and the central region 111a.

The shower head 13 is configured to introduce at least one processing gas from the gas supply 20 into the plasma processing space 10s. The shower head 13 has at least one gas supply port 13a, at least one gas diffusion chamber 13b, and a plurality of gas introduction ports 13c. The processing gas supplied to the gas supply port 13a passes through the gas diffusion chamber 13b and is introduced into the plasma processing space 10s from the gas introduction ports 13c. The shower head 13 further includes at least one upper electrode. The gas introduction unit may include, in addition to the shower head 13, one or a plurality of side gas injectors (SGI) that are attached to one or a plurality of openings formed in the sidewall 10a.

The gas supply 20 may include at least one gas source 21 and at least one flow rate controller 22. In one embodiment, the gas supply 20 is configured to supply at least one processing gas from the respective corresponding gas sources 21 to the shower head 13 via the respective corresponding flow rate controllers 22. The flow rate controller 22 may include, for example, a mass flow controller or a pressure-controlled flow rate controller. Further, the gas supply 20 may include at least one flow rate modulation device that modulates or pulses the flow rate of at least one processing gas.

The power source 30 includes the RF power source 31 coupled to the plasma processing chamber 10 via at least one impedance matching circuit. The RF power source 31 is configured to supply at least one RF signal (RF power) to at least one lower electrode and/or at least one upper electrode. Plasma is thus generated from the at least one processing gas supplied into the plasma processing space 10s. Accordingly, the RF power source 31 may function as at least a part of the plasma generator 12. A bias potential can be generated in the substrate W by supplying the bias signal to at least one lower electrode, and an ionic component in the formed plasma can be attracted to the substrate W.

In one embodiment, the RF power source 31 includes a first RF generator 31a and a second RF generator 31b. The first RF generator 31a is coupled to at least one lower electrode and/or at least one upper electrode via the at least one impedance matching circuit, and is configured to generate a source signal (source RF power) for plasma generation. In one embodiment, the source signal has a frequency in a range of 10 MHz to 150 MHz. In one embodiment, the first RF generator 31a may be configured to generate a plurality of source signals having different frequencies. The generated one or more source signals are supplied to at least one lower electrode and/or at least one upper electrode.

The second RF generator 31b is coupled to the at least one lower electrode via the at least one impedance matching circuit and is configured to generate the bias signal (bias RF power). A frequency of the bias signal may be the same as or different from a frequency of the source signal. In one embodiment, the bias signal has a frequency lower than the frequency of the source signal. In one embodiment, the bias signal has a frequency in a range of 100 kHz to 60 MHz. In one embodiment, the second RF generator 31b may be configured to generate a plurality of bias signals having different frequencies. The generated one or more bias signals are supplied to at least one lower electrode. In various embodiments, at least one of the source signal and the bias signal may be pulsed by on/off control or high/low control.

In one embodiment, the source signal and the bias signal may be pulsed together. At this time, the source signal and the bias signal may be supplied such that an on/off timing or a high/low timing of the source signal is in synchronization with an on/off timing or a high/low timing of the bias signal. Further, the source signal turn-on timing may precede the bias signal turn-on timing. Further, the bias signal turn-on timing may precede the source signal turn-on timing.

In one embodiment, the RF power source 31 is controllably configured to vary the frequency of the bias signal. In this case, the RF power source 31 may be a known frequency variable power source that variably controls the frequency in the second RF generator 31b. Further, a known frequency converter controllably configured to vary the frequency of the bias signal may be provided on a supply path of the bias signal from the RF power source 31 to the lower electrode. In one embodiment, the RF power source 31 is controllably configured to vary the frequency of the source signal. In this case, the RF power source 31 may be a known frequency variable power source that variably controls the frequency in the first RF generator 31a. Further, a known frequency converter controllably configured to vary the frequency of the source signal may be provided on a supply path of the source signal from the RF power source 31 to the upper electrode and/or the lower electrode.

The power source 30 may include the DC power source 32 coupled to the plasma processing chamber 10. The DC power source 32 includes a first DC generator 32a and a second DC generator 32b. In one embodiment, the first DC generator 32a is connected to at least one lower electrode to generate a first DC signal. The generated first DC signal is applied to the at least one lower electrode. In one embodiment, the second DC generator 32b is connected to at least one upper electrode and configured to generate a second DC signal. The generated second DC signal is applied to the at least one upper electrode.

In various embodiments, the first and second DC signals may be pulsed. In this case, a sequence of voltage pulses is applied to at least one lower electrode and/or at least one upper electrode. The voltage pulses may each have a rectangular, trapezoidal, or triangular pulse waveform or a combination thereof. In one embodiment, a waveform generator that generates the sequence of the voltage pulses from a DC signal is connected between the first DC generator 32a and at least one lower electrode. Accordingly, the first DC generator 32a and the waveform generator form a voltage pulse generator. When the second DC generator 32b and the waveform generator form a voltage pulse generator, the voltage pulse generator is connected to at least one upper electrode. The voltage pulse may have a positive polarity or a negative polarity. Further, the sequence of the voltage pulses may include one or more positive voltage pulses and one or more negative voltage pulses in one cycle. The first and second DC generators 32a and 32b may be provided in addition to the RF power source 31, and the first DC generator 32a may be provided instead of the second RF generator 31b. In one embodiment, the waveform generator is controllably configured to vary a voltage pulse frequency when generating the voltage pulse. In this case, the waveform generator may include a known switching mechanism configured to variably control the voltage pulse frequency.

In one embodiment, a unit is provided that measures power (hereinafter, referred to as reflected wave power) reflected from various loads including the upper electrode and the lower electrode when power (hereinafter, referred to as supply waves) is supplied from the RF power source 31. In this case, the unit may be provided in the RF power source 31. Further, the unit may be provided on a supply path of the supply waves from the RF power source 31 to the upper electrode and/or the lower electrode. In this case, the unit may be a reflected wave detector 33a provided on the supply path of the supply waves in the upper electrode and/or a reflected wave detector 33b provided on the supply path of the supply waves in the lower electrode.

The exhaust system 40 may be connected to, for example, a gas exhaust port 10e disposed at a bottom portion of the plasma processing chamber 10. The exhaust system 40 may include a pressure adjusting valve and a vacuum pump. The pressure adjusting valve adjusts a pressure in the plasma processing space 10s. The vacuum pump may include a turbo molecular pump, a dry pump, or a combination thereof.

### <Plasma Processing Method>

Next, a plasma processing method MT1 will be described. The plasma processing method MT1 according to the present disclosure can be executed in the plasma processing system described above, for example. Specifically, when the RF power source 31 is a frequency variable power source, control of varying the frequency in the RF power source 31 may be performed. When a frequency converter is provided, control of varying the frequency in the frequency converter may be performed. Further, when acquiring the reflected wave power as described below, a measurement unit of the reflected wave power, which is provided in the RF power source 31 or on the supply path of the supply power from the RF power source 31 to the upper electrode and/or the lower electrode, may perform measurement and acquire a value. The controller 2 may execute processes such as control and measurement instruction, recording, and calculation. In the present disclosure, source power, bias power, and the reflected wave power are given by squares of amplitudes of the source signal, the bias signal, and the reflected waves, respectively.

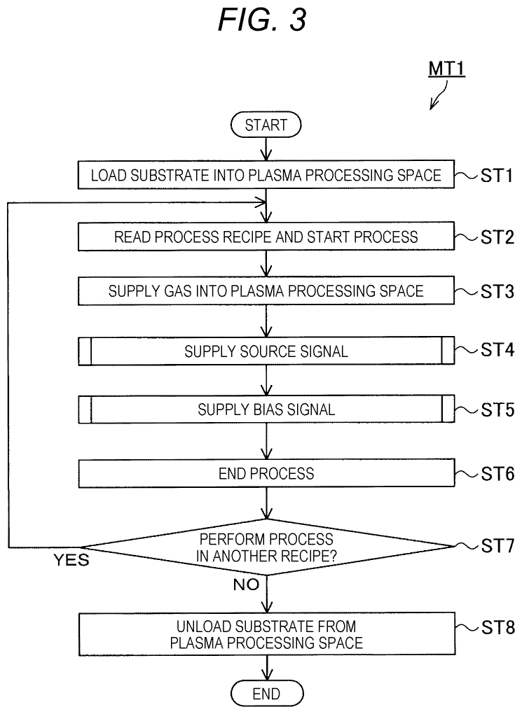

Hereinafter, the plasma processing method MT1 will be described with reference to FIG. 3. FIG. 3 is a flowchart illustrating an outline of the plasma processing method MT1 according to one embodiment. First, a substrate is loaded into a chamber (ST1). Subsequently, a process recipe is read, and one process is started (ST2). Subsequently, a gas is supplied into the chamber with a desired gas type and gas pressure (ST3). Subsequently, a source signal is supplied (ST4). The method of supplying the source signal in step ST4 will be described later. Subsequently, a bias signal is supplied (ST5). The method of supplying the bias signal in step ST5 will be described later. Steps ST4 and ST5 may be performed at the same time. Thereafter, the process ends (ST6). Subsequently, it is determined whether another process is to be performed in another process recipe (ST7). When another process is to be performed, the processing returns to step ST2, the other process recipe is read to perform the other process, and steps ST2 to ST7 are repeated. When no other process is to be performed in step ST7, the substrate is unloaded from the chamber, and the plasma processing method MT1 is ended.

Next, a method of supplying a bias signal to the lower electrode (hereinafter referred to as a bias signal supply method) in the plasma processing method MT1 will be described. The following bias signal supply methods MT10 to MT30 can be performed as step ST5 in the plasma processing method MT1. However, the present disclosure is not limited thereto. For example, by supplying a processing gas into the plasma processing space before the start of the process, and subsequently performing any of the bias signal supply methods MT10 to MT30 described below, it is possible to confirm a plasma ignition condition in the process in advance. Thereafter, the plasma processing method MT1 may be performed, and in step ST5, the bias signal may be supplied using the plasma ignition condition recorded in advance as described above.

### First Embodiment

The bias signal supply method MT10 according to a first embodiment will be described. In the embodiment, a frequency of a bias signal (hereinafter referred to as a bias frequency) is changed every control period to obtain a desired bias frequency. The control period refers to a division of control in unit of a period from one execution of control of changing the value of the bias frequency to another subsequent execution of control of changing the value of the bias frequency to another value. Specifically, in the embodiment, the division of control in unit of steps ST100 to ST108 described below is defined as one control period.

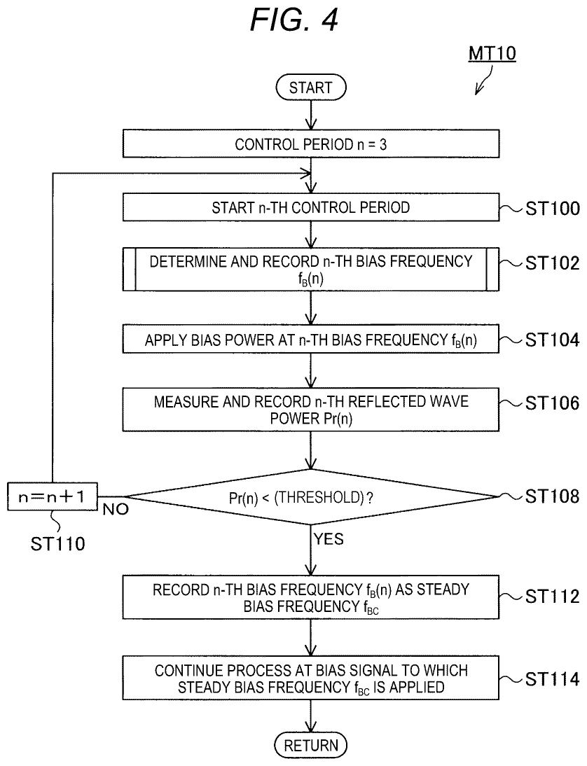

First, an overall flow of the bias signal supply method MT10 according to the first embodiment will be described with reference to FIG. 4. First, an initial value of a control period n is set to (n=3), and the n-th control period is started (ST100). Subsequently, an n-th bias frequency f_{B}(n) is determined and recorded (ST102). A method of determining the n-th bias frequency f_{B}(n) will be described later. Subsequently, a bias signal to which the determined n-th bias frequency f_{B}(n) is applied is supplied (ST104). Subsequently, n-th reflected wave power Pr(n) reflected from a load when the bias signal is supplied is measured and recorded (ST106). Subsequently, a value of the n-th reflected wave power Pr(n) is compared with a threshold to determine a magnitude relationship thereof (ST108). The threshold may be determined in advance according to the process recipe and recorded, and may be read in step ST108. When the value of the n-th reflected wave power Pr(n) is equal to or greater than the threshold in step ST108, the n-th control period is ended, and the next control period is started with (n=n+1) (ST110). In the (n+1)-th control period, the above-described steps ST100 to ST108 performed in the n-th control period are performed again, and thereafter, the above-described steps ST100 to ST108 are repeated in the same manner in an (n+k)-th control period, with k being any natural number. When the value of the n-th reflected wave power Pr(n) is smaller than the desired threshold in step ST108, the n-th bias frequency f_{B}(n) is recorded as a steady bias frequency f_{BC} (ST112). Thereafter, the bias signal to which the steady bias frequency f_{BC} is applied is continuously supplied (ST114).

In the above, a past actual value relating to plasma stability may be used as the threshold for each process. In this case, the threshold may have a desired initial value and be decreased at a specified ratio for each control period or be changed every time a desired time elapses, or these change methods may be freely selected and combined to change the threshold. By determining the threshold in this way, an impedance matching state can be improved with the elapse of the control period or time. The thresholds according to other embodiments to be described later can also be determined in the same manner.

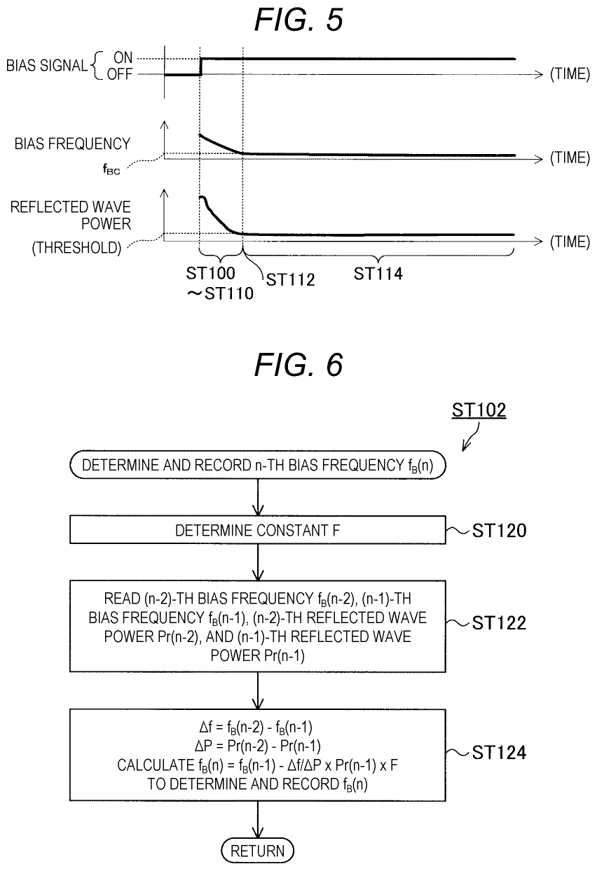

FIG. 5 is a graph illustrating an outline of changes over time of on/off (high/low) of the bias signal, the bias frequency, and the reflected wave power when the bias signal supply method MT10 according to the first embodiment is performed. In step ST100 to step ST110, the reflected wave power decreases along with the change in the bias frequency by loop control. The bias frequency at a point in time when the reflected wave power is smaller than the threshold is recorded as the steady bias frequency f_{BC} (ST112), and the bias signal to which the steady bias frequency f_{BC} is applied is continuously supplied (ST114).

Next, the step (ST102) of determining the n-th bias frequency f_{B}(n) in the bias signal supply method MT10 according to the first embodiment will be described in detail. FIG. 6 is a flowchart illustrating in detail step ST102 of determining the n-th bias frequency f_{B}(n) in FIG. 4. First, a constant F is determined (step ST120). The constant F may be determined in advance according to the process recipe and recorded, and may be read in step ST120. Next, an (n−2)-th bias frequency f_{B}(n−2), an (n−1)-th bias frequency f_{B}(n−1), (n−2)-th reflected wave power Pr(n−2), and (n−1)-th reflected wave power Pr(n−1) are read (ST122). Subsequently, a bias frequency change amount Δf is calculated by calculation using the following Equation (1), a reflected wave power change amount ΔP is calculated by calculation using the following Equation (2), and the n-th bias frequency f_{B}(n) is determined by calculation using the following Equation (3) and recorded.

Δf=f_{B}(n−2)−f_{B}(n−1) . . . (1)

ΔP=Pr(n−2)−Pr(n−1) . . . (2)

f_{B}(n)=f_{B}(n−1)−Δf/ΔP×Pr(n−1)×F . . . (3)

As an example, the constant F may be determined as follows. Plasma is generated in the plasma processing chamber 10 into which a dummy wafer is loaded in advance, and the dummy wafer is processed. At this time, the constant F relating to the plasma stability is searched for according to temporal transition. In the search for the constant F relating to the plasma stability, first, the constant F sufficiently small is used to reduce the bias frequency change amount defined by Equations (1) to (3), and the constant F having an appropriate value to the extent that the stability of the plasma is not lost while gradually increasing the constant F is set to be the constant F used in the above Equation (3).

A first bias frequency f_{B}(1) and a second bias frequency f_{B}(2) may be determined in advance according to the process recipe and recorded, regardless of the above, and may be read in step ST104. As an example, plasma is generated in the plasma processing chamber 10 into which a dummy wafer is loaded in advance, and the dummy wafer is processed. At this time, patterns of temporal transition of several types of bias frequencies may be prepared and processed, and bias frequencies in the patterns when reflection or reflectance is reduced during the processing may be determined as the first bias frequency f_{B}(1) and the second bias frequency f_{B}(2).

Steps ST100 to ST110 form a feedback loop. In this loop, repeated control is performed such that the reflected wave power Pr(n) that may be occur with respect to the bias signal supplied in the n-th control period is smaller than the reflected wave power Pr(n−1) in the (n−1)-th control period. That is, the n-th reflected wave power Pr(n) is expected to be smaller than the (n−1)-th reflected wave power Pr(n−1). In step ST108, it is determined that the reflected wave power is sufficiently small when the reflected wave power occurring with respect to the bias signal supplied in the current control period (the n-th control period) is smaller than the threshold. By using the bias signal to which the steady bias frequency f_{BC} that provides such reflected wave power Pr is applied, the reflected wave power can be reduced to be sufficiently small. In the present specification, the n-th control period may be referred to as the “current control period”, the (n−1)-th control period may be referred to as a “last control period”, and the (n−2)-th control period may be referred to as a “second-to-last control period”.

More specifically, in step ST102, the n-th bias frequency f_{B}(n) is determined using the values of the bias frequencies and the reflected wave power in the (n−1)-th control period and the (n−2)-th control period. Accordingly, the n-th bias frequency f_{B}(n) can be determined such that the n-th reflected wave power Pr(n) is smaller than the (n−1)-th reflected wave power Pr(n−1). The reason therefor will be described together with contributions of respective terms of Equation (3) in step ST102.

The Δf/ΔP×Pr(n−1)×F as the second term on the right side in Equation (3) is subtracted from the f_{B}(n−1) as the first term on the right side in Equation (3). That is, the n-th bias frequency f_{B}(n) is calculated by correcting the (n−1)-th bias frequency f_{B}(n−1) by the second term on the right side in Equation (3).

Here, the ratio Δf/ΔP of the difference Δf between the bias frequencies to the difference ΔP between the reflected wave power in the second term on the right side of Equation (3) will be described. The sign of the ratio Δf/ΔP contributes to a control direction (direction of increase or decrease) of the bias frequency f_{B}(n) in the n-th control period. That is, when Δf>0, it means that control is performed such that the f_{B}(n−1) is decreased compared to the f_{B}(n−2) in the (n−1)-th control period. Further, when Δf<0, it means that control is performed such that the f_{B}(n−1) is increased compared to the f_{B}(n−2) in the (n−1)-th control period. Further, when ΔP>0, it means that the Pr(n−1) is decreased compared to the Pr(n−2) in the (n−1)-th control period. Further, when ΔP≤0, it means that Pr(n−1) is increased or has no change compared to the Pr(n−2) in the (n−1)-th control period. Here, as an example, a case where Δf>0 and ΔP>0 are obtained will be considered. When Δf>0 and ΔP>0 are satisfied, it means that the Pr(n−1) is decreased compared to Pr(n−2) by performing control such that the f_{B}(n−1) is decreased compared to the f_{B}(n−2) in the (n−1)-th control period. In this case, it is expected that Pr(n) will be decreased compared to the Pr(n−1) by performing control such that the f_{B}(n) is decreased compared to the f_{B}(n−1) in the n-th control period as well. When Δf>0 and ΔP>0, Δf/ΔP>0, and since the sign of the second term on the right side in Equation (3) is determined by Δf/ΔP, the sign of the second term on the right side in Equation (3) is determined to be negative (that is, the second term on the right side in Equation (3) is subtracted from the first term on the right side in Equation (3). When the sign of the second term on the right side in Equation (3) is negative, the f_{B}(n) decreases compared to the f_{B}(n−1). Similarly, when Δf<0 and ΔP>0, Δf/ΔP<0, and the sign of the second term on the right side in Equation (3) is positive. When Δf>0 and ΔP<0, Δf/ΔP<0, and the sign of the second term on the right side in Equation (3) is positive. When Δf<0 and ΔP<0, Δf/ΔP>0, and the sign of the second term on the right side in Equation (3) is negative. In this way, the control direction (direction of increase or decrease) of the bias frequency f_{B}(n) in the n-th control period can be determined using the sign of the ratio Δf/ΔP.

From this viewpoint, a configuration may be adopted in which reference is made only to the sign of the ratio Δf/ΔP in Equation (3), the difference Δf being between the bias frequencies and the difference ΔP being between the reflected wave power. That is, in Equation (3), instead of the ratio Δf/ΔP, (Δf/ΔP)/|Δf/ΔP| can be used as the sign of the ratio Δf/ΔP, and the following Equation (3-1) can be derived.

f(n)=f(n−1)−(Δf/ΔP)/|Δf/ΔP|×|ΔP|×F . . . (3-1)

In the second term on the right side in Equation (3), an absolute value of the value of the ratio Δf/ΔP, the value of Pr(n−1), and the constant F each contribute to a control amount, and the control amount is given by a product thereof. Specifically, the control amount is calculated to be larger as the value of Δf is larger, the value of AP is smaller, and the value of Pr(n−1) is larger.

By determining the control direction and the control amount as described above, the values of the bias frequencies and the reflected wave power as a result of control in the (n−1)-th control period and the (n−2)-th control period can be reflected in the n-th bias frequency f_{B}(n) determined in the n-th control period.

According to the embodiment described above, the n-th bias frequency f_{B}(n) can be determined such that the n-th reflected wave power Pr(n) is smaller than the threshold, and the steady bias frequency f_{BC} can be obtained. By using the bias signal to which the steady bias frequency f_{BC} is applied, the process can be continued while reducing the reflected wave power to be sufficiently small.

Although the n-th bias frequency f_{B}(n) is determined using the value of the reflected wave power in the embodiment described above, the present disclosure is not limited thereto. The reflected wave power is one parameter that quantitatively indicates the impedance matching state. Therefore, similar to the reflected wave power, another desired parameter relating to matching states of the impedances acquired in the last and second-to-last control periods can be used to determine the n-th bias frequency f_{B}(n). As the other parameter relating to the impedance matching state, for example, a ratio of the reflected wave power to input bias power, that is, the reflectance (reflected wave power/input bias power) can be used. Further, for example, as the other parameter relating to the impedance matching state, a voltage V, a current I, and a phase difference θ between the voltage V and the current I of the bias signal can be used. Further, the bias frequency f_{B}(n) may be changed such that a value of the impedance approaches a predetermined value (for example, 50Ω). This also applies to the following embodiments.

### Second Embodiment

A bias signal supply method MT20 according to a second embodiment will be described. In the embodiment, a bias signal pulsed by on/off control or high/low control is supplied. At this time, the bias frequency is changed for each control period to obtain a desired bias frequency. Further, the control of the bias frequency is performed for each control period of each pulse period. Regarding the pulse, in the case of on/off control, one pulse is defined as a period from when the bias signal is turned on to when the bias signal is turned off, and one pulse period is defined as a period from the start and end of one pulse to the start of the next pulse. Further, in the case of high/low control, one pulse is defined as a period from when the bias signal is set to be high to when the bias signal is set to be low, and one pulse period is defined as a period from the start of one pulse to the start of the next pulse. In the embodiment, specifically, a division of control in unit of steps ST200 to ST220 described below is defined as one pulse period. Further, in the embodiment, specifically, a division of control in unit of steps ST202 to ST210 described below is defined as one control period. Further, in the present disclosure, for distinguishment, an n-th control period in an m-th pulse is described as an (m, n)-th control period, the n-th control period in an (m−1)-th pulse is described as an (m−1, n)-th control period, an (n−1)-th control period in the m-th pulse is described as an (m, n−1)-th control period, and an (n−1)-th control period in the (m−1)-th pulse is described as an (m−1, n−1)-th control period.

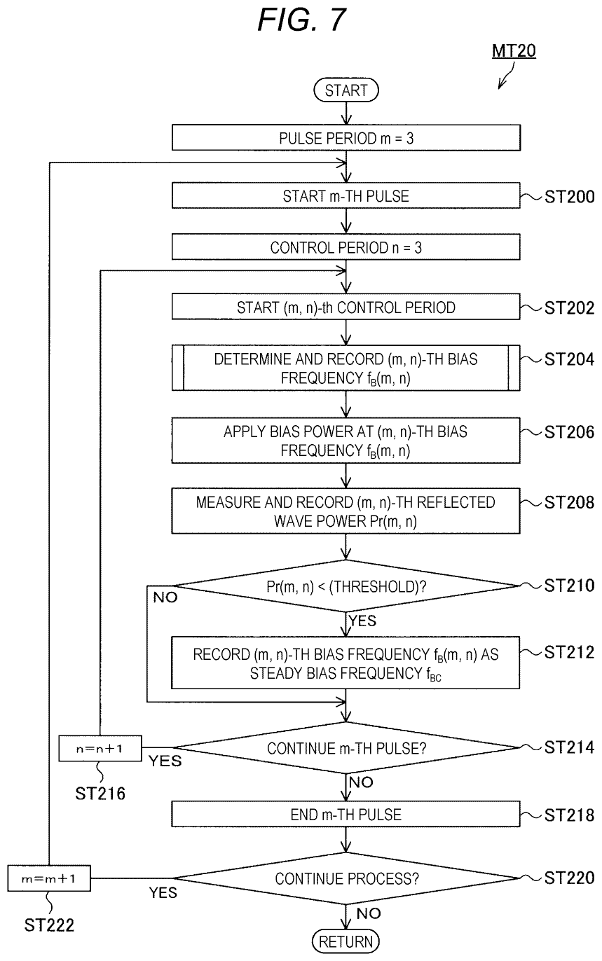

First, an overall flow of the bias signal supply method MT20 according to the second embodiment will be described with reference to FIG. 7. First, an initial value of the pulse period m is set to (m=3), and the m-th pulse is started (ST200). Subsequently, an initial value of the control period n is set to (n=3), and the (m, n)-th control period in the m-th pulse is started (ST202). Subsequently, an (m, n)-th bias frequency f_{B}(m, n) is determined and recorded (ST204). A method of determining the (m, n)-th bias frequency f_{B}(m, n) will be described later. Subsequently, a bias signal to which the determined (m, n)-th bias frequency f_{B}(m, n) is applied is supplied (ST206). Subsequently, when the bias signal is supplied, (m, n)-th reflected wave power Pr(m, n) reflected from a load is measured and recorded (ST208). Subsequently, a value of the (m, n)-th reflected wave power Pr(m, n) is compared with the a threshold to determine a magnitude relationship thereof (ST210). The threshold may be determined in advance according to a process recipe and recorded, and may be read in step ST210. When the value of the (m, n)-th reflected wave power Pr(m,n) is smaller than the threshold in step ST210, the (m, n)-th bias frequency f_{B}(m, n) is recorded as the steady bias frequency f_{BC} (ST212). Further, when the value of the (m, n)-th reflected wave power Pr(m, n) is equal to or greater than the threshold in step ST210, a determination is made as to whether to continue the m-th pulse (ST214). Whether to continue the m-th pulse may be determined by determining whether a desired time elapses since the start of the pulse, based on a pulse interval determined in advance according to the process recipe. When the m-th pulse is to be continued in step ST214, the (m, n)-th control period is ended, and the next control period is started with (n=n+1) (ST216). In the (m, n+1)-th control period, the above-described steps ST202 to ST214 performed in the (m, n)-th control period are performed again, and thereafter, the above-described steps ST202 to ST214 are repeated in the same manner in an (m, n+k)-th control period, with k being any natural number. When the m-th pulse is not to be continued in step ST214, the m-th pulse is ended (ST218). Subsequently, it is determined whether to continue the process (step ST220). When the process is not to be continued, the process is ended. When the process is to be continued, the next pulse period is started with (m=m+1) (ST222). In the (m+1)-th pulse, the above-described steps ST200 to ST220 performed in the m-th pulse are performed again, and thereafter, the above-described steps ST200 to ST220 are repeated in the same manner in an (m+j)-th pulse, with j being any natural number.

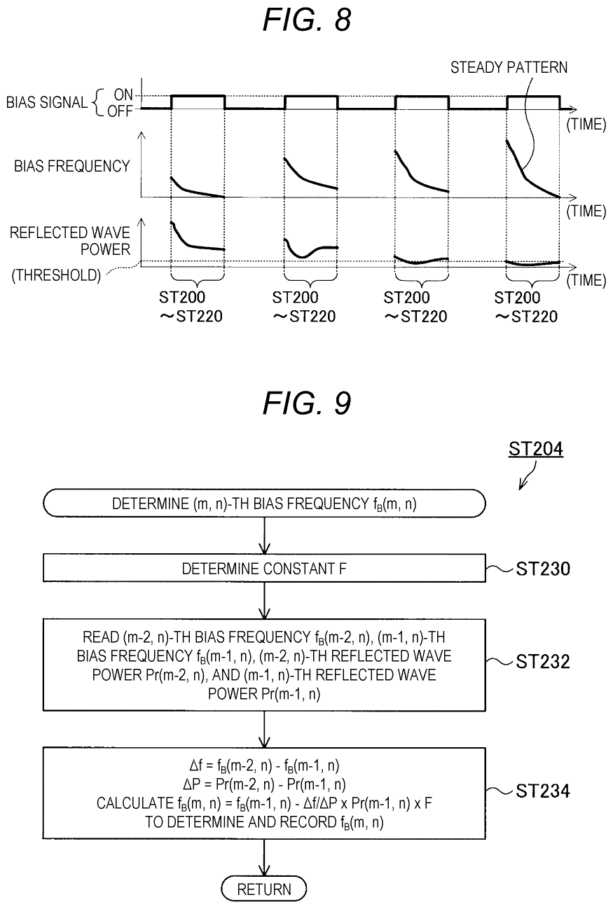

FIG. 8 is a graph illustrating an outline of changes over time of on/off (high/low) of the bias signal, the bias frequency, and the reflected wave power when the bias signal supply method MT20 according to the second embodiment is performed. Steps ST200 to ST220 are repeated for each pulse period. In the pulses, the bias frequency is determined with reference to the reflected wave power in the same control periods of the last ((m−1)-th pulse) pulse and the second-to-last ((m−2)-th pulse) pulse. Therefore, the reflected wave power in the current control period of the current pulse (the m-th pulse) is smaller than the reflected wave power in the same control periods of the last and second-to-last pulses. A case is conceivable in which the reflected wave power is smaller than the threshold in all control periods in a certain pulse period by repeating steps ST200 to ST220. A control pattern of the frequency in the pulse period is referred to as a steady pattern. Details of the steady pattern will be described later. In the present specification, the m-th pulse may be referred to as the “current pulse”, the (m−1)-th pulse may be referred to as the “last pulse”, and the (m−2)-th pulse may be referred to as the “second-to-last pulse”.

Next, the step (ST204) of determining the (m, n)-th bias frequency f_{B}(m, n) in the bias signal supply method MT20 according to the second embodiment will be described in detail. FIG. 9 is a flowchart illustrating in detail the step of determining the (m, n)-th bias frequency f_{B}(m, n) in FIG. 7. First, the constant F is determined (ST230). The constant F may be determined in advance according to the process recipe and recorded, and may be read in step ST230. Next, an (m−2, n)-th bias frequency f_{B}(m−2, n), an (m−1, n)-th bias frequency f_{B}(m−1, n), (m−2, n)-th reflected wave power Pr(m−2, n), and (m−2, n)-th reflected wave power Pr(m−2, n) are read. Subsequently, the bias frequency change amount Δf is calculated by calculation using the following Equation (4), the reflected wave power change amount ΔP is calculated by calculation using the following Equation (5), and the (m, n)-th bias frequency f_{B}(m, n) is determined by calculation using the following Equation (6) and recorded.

Δf=f_{B}(m−2,n)−f_{B}(m−1,n) . . . (4)

ΔP=Pr(m−2,n)−Pr(m−1,n) . . . (5)

f_{B}(m,n)=f_{B}(m−1,n)−Δf/ΔP×Pr(m−1,n)×F . . . (6)

Here, with respect to the step (ST204) of determining the (m, n)-th bias frequency f_{B}(m, n), when the (m−1, n)-th bias frequency f_{B}(m−1, n) is recorded as the steady bias frequency f_{BC}, the steady bias frequency f_{BC} may be used as the (m, n)-th bias frequency f_{B}(m, n) regardless of the above. At this time, the steady bias frequency f_{BC} can take a different value for each control period. When the steady bias frequencies f_{BC} are recorded in all the control periods, a combination of the steady bias frequencies f_{BC} can be recorded as a steady pattern. In pulse periods after the steady pattern is acquired, the bias signal may be supplied using the steady pattern. Accordingly, as described with reference to FIG. 8, the bias signal can be supplied such that the reflected wave power is smaller than the threshold in all control periods. In the determination of the steady pattern, when the steady bias frequencies f_{BC} are recorded in not all control periods but a desired ratio of the control periods, a combination of such steady bias frequencies f_{BC} may be determined as the steady pattern.

After the determination of the steady pattern, steps ST202 to ST212 may be performed every desired number of pulses occur or every desired time elapses to check that the value of the reflected wave power is smaller than the threshold. As an example, the desired time is 1 ms to 10 ms for a first check, subseconds for a second check, and several minutes for a third check, and the reflected wave power is checked for each of the first to third checks to correct the bias frequency.

Steps ST202 to ST212 form a feedback loop. In this loop, repeated control is performed such that the reflected wave power Pr(m, n) that may occur with respect to the bias signal supplied in the (m, n)-th control period is smaller than the reflected wave power Pr(m−1, n) in the n-th control period of the (m−1)-th pulse. That is, the (m, n)-th reflected wave power Pr(m, n) is expected to be smaller than (m−1, n)-th reflected wave power Pr(m−1, n). In step ST210, it is determined that the reflected wave power is sufficiently small when the reflected wave power occurring with respect to the bias signal supplied this time is smaller than the threshold. By using the bias signal to which the steady bias frequency f_{BC} that provides such reflected wave power Pr is applied, the reflected wave power can be reduced to be sufficiently small.

More specifically, in step ST204, the n-th bias frequency f_{B}(n) is determined using the values of the bias frequencies and the reflected wave power in the (m−1, n)-th control period and an (m−2, n)-th control period. That is, the (m, n)-th bias frequency f_{B}(m, n) in the current pulse period is determined by referring to the values of the bias frequency and the reflected wave power in the same control period in the last and second-to-last pulse periods. Accordingly, the n-th bias frequency f_{B}(m, n) can be determined such that the (m, n)-th reflected wave power Pr(m, n) is smaller than the (m−1, n)-th reflected wave power Pr(m−1, n). The reason therefor will be described together with contributions of respective terms of Equation (6) in step ST204.

The second term Δf/ΔP×Pr(m−1, n)×F on the right side in Equation (6) is subtracted from the f_{B}(m−1, n) as the first term on the right side in Equation (6). That is, the (m, n)-th bias frequency f_{B}(m, n) is calculated by correcting the (m−1, n)-th bias frequency f_{B}(m−1, n) by the second term on the right side in Equation (6).

The ratio Δf/ΔP of the difference Δf between the bias frequencies to the difference ΔP between the reflected wave power in the second term on the right side of Equation (6) will be described. The sign of the ratio Δf/ΔP contributes to the control direction of the bias frequency f_{B}(m, n) in the (m, n)-th control period. That is, when Δf>0, it means that control is performed such that f_{B}(m−1, n) is decreased compared to f_{B}(m−2, n) in the (m−1, n)-th control period. Further, when Δf<0, it means that control is performed such that f_{B}(m−1, n) is increased compared to f_{B}(m−2, n) in the (m−1, n)-th control period. Further, when ΔP>0, it means that Pr(m−1, n) is smaller than Pr(m−2, n) in the (m−1, n)-th control period. Further, when ΔP≤0, it means that Pr(m−1, n) is increased or has no change compared to Pr(m−2, n) in the (m−1, n)-th control period. Here, as an example, a case where Δf>0 and ΔP>0 are obtained will be considered. When Δf>0 and ΔP>0 are satisfied, it means that Pr(m−1, n) is decreased compared to Pr(m−2, n) by performing control such that f_{B}(m−1, n) is decreased compared to f_{B}(m−2, n) in the (m−1, n)-th control period. In this case, it is expected that Pr(m, n) will be decreased compared to Pr(m−1, n) by performing control such that f_{B}(m, n) is decreased compared to f_{B}(m−1, n) in the (m, n)-th control period as well. When Δf>0 and ΔP>0, Δf/ΔP>0, and since the sign of the second term on the right side in Equation (6) is determined by Δf/ΔP, the sign of the second term on the right side in Equation (6) is determined to be negative (that is, the second term on the right side in Equation (6) is subtracted from the first term on the right side in Equation (6)). When the sign of the second term on the right side in Equation (6) is negative, f_{B}(m, n) decreases compared to f_{B}(m−1, n). Similarly, when Δf<0 and ΔP>0, Δf/ΔP<0, and the sign of the second term on the right side in Equation (6) is positive. When Δf>0 and ΔP<0, Δf/ΔP<0, and the sign of the second term on the right side in Equation (6) is positive. When Δf<0 and ΔP<0, Δf/ΔP>0, and the sign of the second term on the right side in Equation (6) is negative. In this way, the control direction of the bias frequency f_{B}(m, n) in the (m, n)-th control period can be determined using the sign of the ratio Δf/ΔP.

In the second term on the right side in Equation (6), an absolute value of the value of the ratio Δf/ΔP, the value of Pr(m−1, n), and the constant F each contribute to a control amount, and the control amount is given by a product thereof. Specifically, the control amount is calculated to be larger as the value of Δf is larger, the value of ΔP is smaller, and the value of Pr(m−1, n) is larger.

By determining the control direction and the control amount as described above, the values of the bias frequencies and the reflected wave power as a result of control in the (m−1, n)-th control period and the (m−2, n)-th control period can be reflected in the (m, n)-th bias frequency f_{B}(m, n) determined in the (m, n)-th control period.

According to the embodiment described above, the (m, n)-th bias frequency f_{B}(m, n) can be determined such that the (m, n)-th reflected wave power Pr(m, n) is smaller than the threshold. Further, the steady pattern can be determined such that the reflected wave power Pr(m, n) is smaller than the threshold in a desired ratio of control periods. By using the bias signal to which the steady pattern is applied, the process can be continued while reducing the reflected wave power to be sufficiently small.

Although the last and second-to-last pulse periods are referred to in Equations (4) to (6), the present disclosure is not limited thereto. For example, the current bias frequency may be determined with reference to an (m−h)-th pulse and an (m−h−1)-th pulse with h being a desired integer of 2 or more.

### Third Embodiment

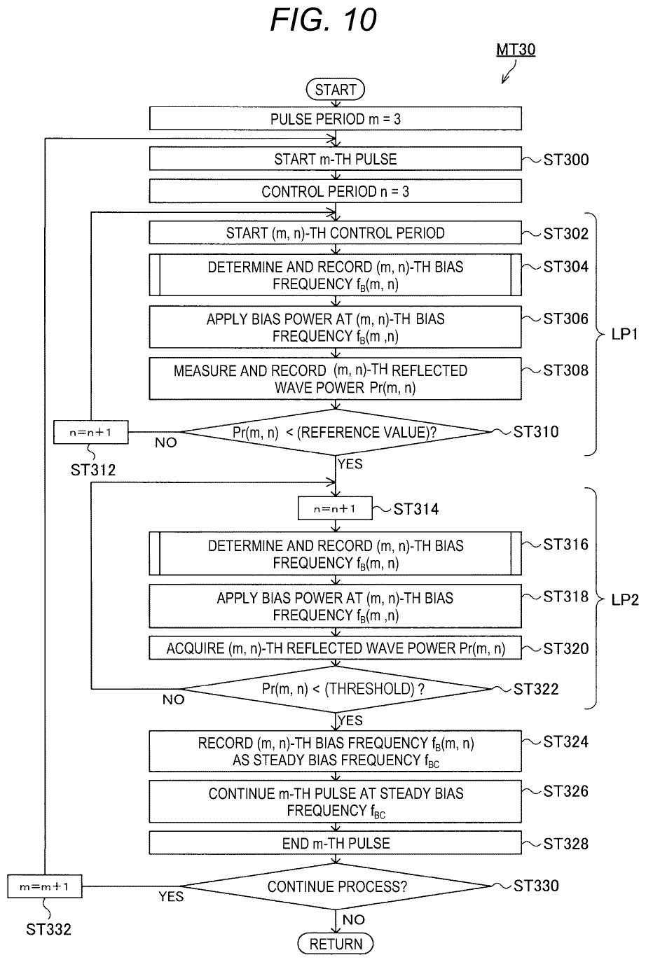

A bias signal supply method according to a third embodiment will be described with reference to FIG. 10. In the embodiment, a bias signal pulsed by on/off control or high/low control is supplied. At this time, the bias frequency is changed for each control period to obtain a desired bias frequency. Further, the control of the bias frequency is performed for each control period of each pulse period.

The bias signal supply method according to the third embodiment is characterized in that first loop control LP1 and second loop control LP2 are consecutively performed. Specifically, first, in the first loop control LP1, similarly to the bias signal supply method MT20 according to the second embodiment, the (m, n)-th bias frequency f_{B}(m, n) in the current pulse period is determined by referring to values of the bias frequency and the reflected wave power in the same control period in the last and second-to-last pulse periods. Thereafter, in the second loop control LP2, similarly to the bias signal supply method MT10 according to the first embodiment, the (m, n)-th bias frequency f_{B}(m, n) in the current control period is determined by referring to the values of the bias frequencies and the reflected wave power in the last and second-to-last control periods.

An overall flow of the bias signal supply method according to the third embodiment will be described. First, an initial value of the pulse period m is set to (m=3), and the m-th pulse is started (ST300). Subsequently, an initial value of the control period n is set to (n=3), and the (m, n)-th control period in the m-th pulse is started (ST302). Subsequently, the (m, n)-th bias frequency f_{B}(m, n) is determined and recorded (ST304). As the method of determining the (m, n)-th bias frequency f_{B}(m, n), a determination method defined for step ST204 in the bias signal supply method MT20 according to the second embodiment can be used. Subsequently, a bias signal to which the determined (m, n)-th bias frequency f_{B}(m,n) is applied is supplied (ST306). Subsequently, when the bias signal is supplied, the (m, n)-th reflected wave power Pr(m, n) reflected from a load is measured and recorded (ST308). Subsequently, a value of the (m, n)-th reflected wave power Pr(m, n) is compared with a reference value to determine a magnitude relationship thereof (ST310). The reference value may be determined in advance according to a process recipe and recorded, and may be read in step ST310. When the value of the (m, n)-th reflected wave power Pr(m, n) is equal to or greater than the reference value in step ST310, the current control period is ended, and the next control period is started with (n=n+1) (ST312). After step ST312, in the next control period, the above-described steps ST302 to ST310 performed in the (m, n)-th control period are performed again, and thereafter, the above-described steps ST302 to ST310 are repeated in the same manner in an (m, n+k)-th control period, with k being any natural number. When the value of the (m, n)-th reflected wave power Pr(m, n) is smaller than the reference value in step ST310, the (m, n)-th control period is ended, and the next control period is started with (n=n+1) (ST314). Repeating steps ST302 to ST310 is referred to as the first loop control LP1, and the first loop control LP1 ends when the value of the (m, n)-th reflected wave power Pr(m, n) is smaller than the reference value in step ST310.

In the above, the reference value can be determined similarly to the threshold. That is, the reference value may be a past actual value relating to plasma stability for each process. In this case, the reference value may have a desired initial value and be decreased at a specified ratio for each control period or be changed every time a desired time elapses, or these change methods may be freely selected and combined to change the reference value. By determining the reference value in this way, an impedance matching state can be improved with the control period the elapse of or time.

With respect to the step (ST304) of determining the (m, n)-th bias frequency f_{B}(m, n), when the (m−1, n)-th bias frequency f_{B}(m−1, n) is recorded as the steady bias frequency f_{BC}, the steady bias frequency f_{BC} may be used as the (m, n)-th bias frequency f_{B}(m, n) regardless of the above. Here, the steady bias frequency f_{BC} can take a different value for each control period. When the steady bias frequencies f_{BC} are recorded in all the control periods, a combination of the steady bias frequencies f_{BC} may be recorded as a steady pattern, and the bias signal may be supplied using the steady pattern in the subsequent pulse periods. When the steady bias frequencies f_{BC} are recorded in not all control periods but a desired ratio of the control periods, a combination of the steady bias frequencies f_{BC} may be set as the steady pattern.

The first loop control LP1 ends, and in the next control period after step ST314, the (m, n)-th bias frequency f_{B}(m, n) is determined and recorded (ST316). The method of determining the (m, n)-th bias frequency f_{B}(m, n) in step ST316 will be described later. Subsequently, the bias signal to which the determined (m, n)-th bias frequency f_{B}(m, n) is applied is supplied (ST318). Subsequently, when the bias signal is supplied, the (m, n)-th reflected wave power Pr(m, n) reflected from the load is measured and recorded (ST320). Subsequently, the value of the (m, n)-th reflected wave power Pr(m, n) is compared with a threshold to determine a magnitude relationship thereof (ST322). The threshold may be determined in advance according to the process recipe and recorded, and may be read in step ST322. In step ST322, when the value of the (m, n)-th reflected wave power Pr(m, n) is equal to or greater than the threshold, the current control period is ended, and the next control period is started with (n=n+1). In the next control period, steps ST316 to ST322 performed in the (m, n)-th control period are performed again, and thereafter, steps ST316 to ST322 are repeated in the same manner in the (m, n+k)-th control period with k being any natural number. In step ST322, when the value of the (m, n)-th reflected wave power Pr(m, n) is smaller than the threshold, the (m, n)-th bias frequency f_{B}(m, n) is recorded as the steady bias frequency f_{BC} (ST324). Repeating steps ST316 to ST322 is referred to as the second loop control LP2, and the second loop control LP2 ends when the value of the (m, n)-th reflected wave power Pr(m, n) is smaller than the threshold in step ST322.

After the second loop control LP2 is ended, the bias signal in the m-th pulse to which the steady bias frequency f_{BC} is applied is continuously supplied (ST326). Subsequently, the m-th pulse is ended after a desired time elapses (ST328). Subsequently, it is determined whether to continue the process (step ST330). When the process is not to be continued, the process is ended. When the process is to be continued, the next pulse period is started with (m=m+1) (ST332). In the (m+1)-th pulse, the above-described steps ST300 to ST330 performed in the m-th pulse are performed again, and thereafter, the above-described steps ST300 to ST330 are repeated in the same manner in an (m+j)-th pulse with j being any natural number.

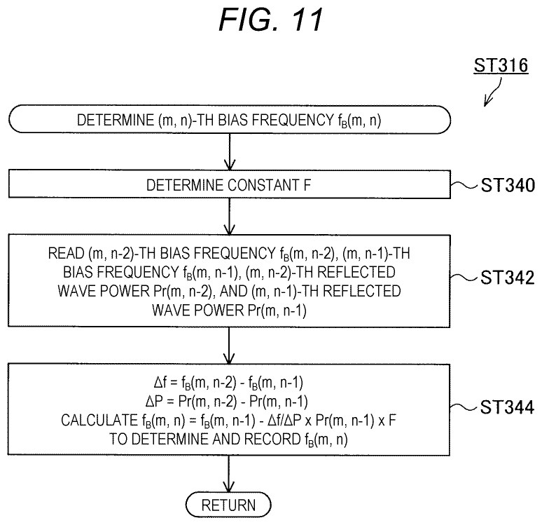

Next, the step (ST316) of determining the (m, n)-th bias frequency f_{B}(m, n) in the second loop control LP2 of the bias signal supply method according to the third embodiment will be described in detail. FIG. 11 is a flowchart illustrating in detail step ST316 of determining the (m, n)-th bias frequency f_{B}(m, n) in FIG. 10. First, the constant F is determined (ST340). The constant F may be determined in advance according to the process recipe and recorded, and may be read in step ST340. Next, an (m, n−2)-th bias frequency f_{B}(m,n−2), an (m, n−1)-th bias frequency f_{B}(m, n−1), (m, n−2)-th reflected wave power Pr(m, n−2), and the (m, n−1)-th reflected wave power Pr(m, n−1) are read. Subsequently, the bias frequency change amount Δf is calculated by calculation using the following Equation (7), the reflected wave power change amount ΔP is calculated by calculation using the following Equation (8), and the (m, n)-th bias frequency f_{B}(m, n) is determined by calculation using the following Equation (9) and recorded.

Δf=f_{B}(m,n−2)−f_{B}(m,n−1) . . . (7)

ΔP=Pr(m,n−2)−Pr(m,n−1) . . . (8)

f_{B}(m,n)=f_{B}(m,n−1)−Δf/ΔP×Pr(m,n−1)×F . . . (9)

The first loop control LP1 and the second loop control LP2 each constitute a feedback loop. In the first loop control LP1, repeated control is performed such that the reflected wave power Pr(m, n) that may occur with respect to the bias signal supplied in the (m, n)-th control period is smaller than the reflected wave power Pr(m−1, n) in the n-th control period of the (m−1)-th pulse. That is, the (m, n)-th reflected wave power Pr(m, n) is expected to be smaller than (m−1, n)-th reflected wave power Pr(m−1, n). In step ST310, when the reflected wave power occurring with respect to the bias signal supplied this time is smaller than the reference value, the first loop control LP1 is ended, and the second loop control LP2 is started in the next control period.

In the first loop control LP1, more specifically, in step ST304, the n-th bias frequency f_{B}(n) is determined using the values of the bias frequencies and the reflected wave power in the (m−1, n)-th control period and the (m−2, n)-th control period. That is, the (m, n)-th bias frequency f_{B}(m, n) in the current pulse period is determined by referring to the values of the bias frequency and the reflected wave power in the same control period in the last and second-to-last pulse periods. Accordingly, the n-th bias frequency f_{B}(m, n) can be determined such that the (m, n)-th reflected wave power Pr(m, n) is smaller than the (m−1, n)-th reflected wave power Pr(m−1, n). The reason therefor is the same as that described for step ST204 in the bias signal supply method MT20 according to the second embodiment, and thus overlapping descriptions thereof have been omitted.

In the second loop control LP2, repeated control is performed such that the reflected wave power Pr(m, n) that may occur with respect to the bias signal supplied in the (m, n)-th control period is smaller than the reflected wave power Pr(m, n−1) that may occur with respect to the bias signal supplied in the (m, n−1)-th control period. That is, the (m, n)-th reflected wave power Pr(m, n) is expected to be smaller than the (m, n−1)-th reflected wave power Pr(m, n−1). In step ST322, it is determined that the reflected wave power is sufficiently small when the reflected wave power occurring with respect to the bias signal supplied this time is smaller than the threshold. By using the bias signal to which the steady bias frequency f_{BC} that provides such reflected wave power Pr is applied, the reflected wave power can be reduced to be sufficiently small.

More specifically, in step ST316, the n-th bias frequency f_{B}(n) is determined using the values of the bias frequencies and the reflected wave power in the (m−1, n)-th control period and the (m−2, n)-th control period. That is, the (m, n)-th bias frequency f_{B}(m, n) in the current pulse period is determined by referring to the values of the bias frequency and the reflected wave power in the same control period in the last and second-to-last pulse periods. Accordingly, the n-th bias frequency f_{B}(m, n) can be determined such that the (m, n)-th reflected wave power Pr(m, n) is smaller than the (m−1, n)-th reflected wave power Pr(m−1, n). The reason therefor is the same as that described for step ST102 in the bias signal supply method MT10 according to the first embodiment, and thus overlapping descriptions thereof have been omitted.

According to the embodiment described above, the (m, n)-th bias frequency f_{B}(m, n) can be determined such that the (m, n)-th reflected wave power Pr(m, n) is smaller than the threshold, and the steady bias frequency f_{BC} can be obtained. By using the bias signal to which the steady bias frequency f_{BC} is applied, the reflected wave power can be reduced to be sufficiently small.

The case of supplying the pulsed source signal in step ST4 of the plasma processing method MT1 will be supplemented as follows. When an on/off timing or high/low timing of the source signal and an on/off timing or high/low timing of the bias signal of the bias signal supply method according to the second or third embodiment are supplied in synchronization with each other, it is preferable to reacquire the steady bias frequency f_{BC} for each power of the source signal supplied in step ST4. This is because the reflected wave power depends on the source signal, and specifically for the following reasons. That is, when the source signal is supplied, a plasma density in the plasma processing space increases. When the plasma density increases, a plasma sheath decreases in thickness. When the plasma sheath decreases in thickness, the electrostatic capacitance occurring when the plasma sheath is regarded as a capacitor increases. When the electrostatic capacitance increases, the impedance decreases, and the impedance as the plasma processing space decreases. When the impedance changes to be low, a reflection amount of the RF power changes.

Next, a method of supplying a source signal to the upper electrode and/or the lower electrode in the plasma processing method MT1 (hereinafter, referred to as a source signal supply method) will be described. A source signal supply method MT40 described below can be performed as step ST4 in the plasma processing method MT1. However, the present disclosure is not limited thereto. For example, by supplying a gas corresponding to the process recipe before the start of the process, and subsequently executing the source signal supply method MT40 described below, it is possible to check and record a plasma ignition condition in the process in advance. Thereafter, the plasma processing method MT1 may be performed, and in step ST4, the source signal may be supplied using the plasma ignition condition recorded in advance as described above.

In the following description, regarding whether the plasma is ignited, the emission of light from the plasma processing space may be detected using OES, and a controller may make a determination based on obtained information. Further, regarding whether the plasma is ignited, the reflected wave power may be measured and the controller may make a determination based on obtained information.

### Fourth Embodiment

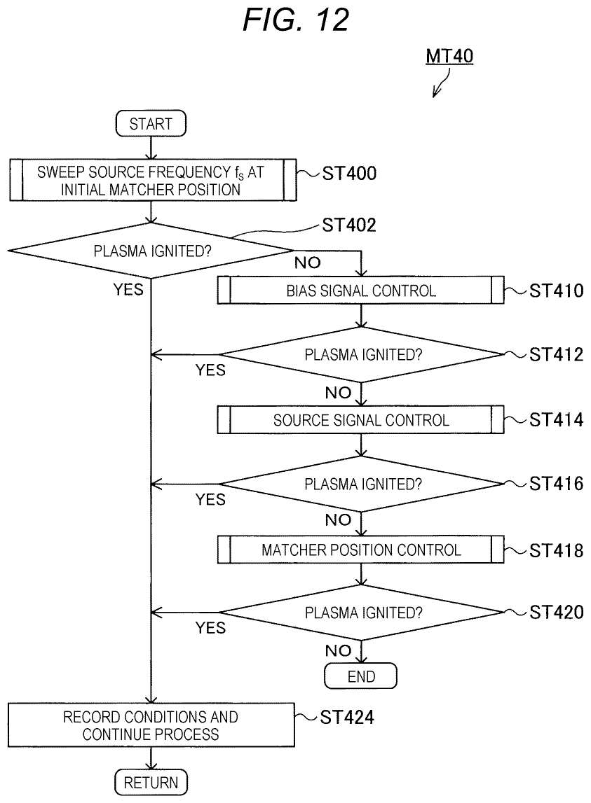

FIG. 12 is a flowchart illustrating an outline of the source signal supply method MT40 according to a fourth embodiment. First, an overall flow of the source signal supply method will be described. First, a sweep of a source frequency f_{S} is performed at an initial matcher position (ST400). The initial matcher position and the sweep will be described in detail later. Subsequently, it is determined whether the plasma is ignited as a result of the sweep (ST402). When the ignition of the plasma is not confirmed in step ST402, subsequently, bias signal control is performed (ST410), and it is determined whether the plasma is ignited as a result thereof (ST412). The details of the bias signal control will be described later. When the ignition of the plasma is not confirmed in step ST412, subsequently, source signal control is performed (ST414), and it is determined whether the plasma is ignited as a result thereof (ST416). Details of the source signal control will be described later. When the ignition of the plasma is not confirmed in step ST416, subsequently, matcher position control is performed (ST418), and it is determined whether the plasma is ignited as a result thereof (ST420). Details of the matcher position control will be described later. When the ignition of the plasma is not confirmed in step ST420, a steady frequency band is recalculated, and step ST400 and subsequent steps are performed again using the recalculated steady frequency band. When the ignition of the plasma is confirmed in steps ST402, ST412, ST416, and ST420, the conditions at the time of the ignition are recorded, and the process is continued (ST424). The conditions at the time of ignition include conditions such as the source frequency f_{S}, the bias signal, the source signal, and the matcher position at the point of time of ignition in the sweep.

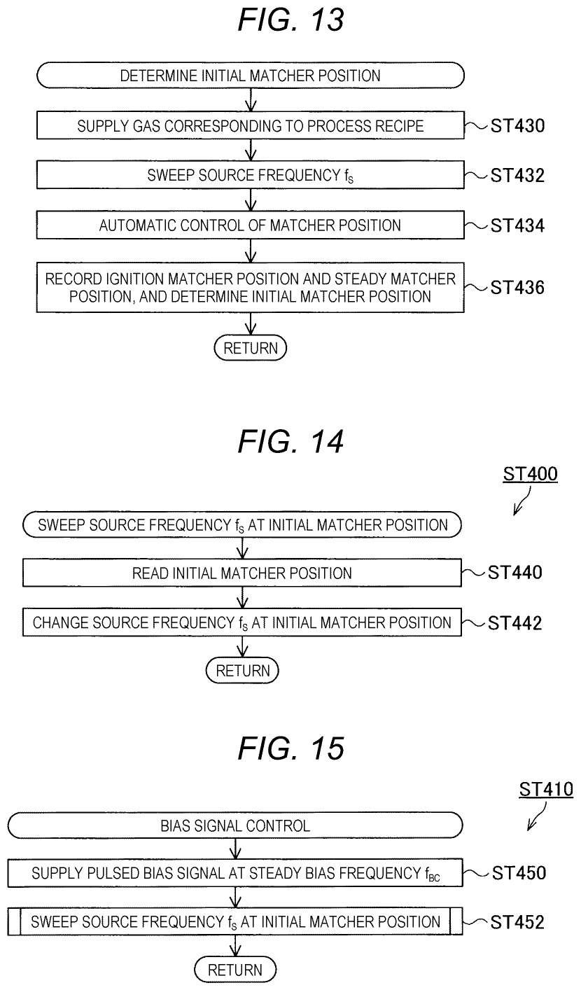

Next, a method of determining the initial matcher position in step ST400 will be described with reference to FIG. 13. FIG. 13 is a flowchart illustrating an outline of the method of determining the initial matcher position before performing the source signal supply method or before performing the sweep in step ST400. First, a gas corresponding to the process recipe is supplied to the plasma processing space (ST430), and the sweep is performed at any source frequency f_{S} (ST432). Control is performed to automatically change the matcher position to match impedances of the RF power source and the plasma processing space when the sweep is performed (ST434). The matcher position at the time when the plasma is ignited as a result of the sweep is recorded as an ignition matcher position, and then a matcher position at the time when the plasma is stabilized is recorded as a steady matcher position (ST434). In one embodiment, the steady matcher position is the initial matcher position. In one embodiment, a position at which the plasma may be ignited through the execution of the bias signal control ST410 or the source signal control ST414 and which is a position between the ignition matcher position and the steady matcher position is determined in advance as the initial matcher position. Further, in one embodiment, the source frequency f_{S} at the time of plasma ignition may be recorded as a steady source frequency f_{SC}, an upper limit frequency and a lower limit frequency may be determined so as to include the steady source frequency f_{SC}, and the frequency range may be defined as the steady frequency band and used for the following steps.

Hereinafter, a source frequency sweep at the initial matcher position will be described with reference to FIG. 14. FIG. 14 is a flowchart illustrating an outline of the source frequency sweep at the steady matcher position performed in step ST400 in FIG. 13. First, the initial matcher position that is determined and recorded in advance is read (ST438). Subsequently, the source frequency f_{S} is changed to change the value of the frequency at the read initial matcher position (ST440). The sweep is performed in any frequency band. In one embodiment, the sweep may be performed in the steady frequency band. In this case, in the source frequency sweep, for example, in step ST440, the source frequency f_{S} may be changed in a manner of decreasing the value of the frequency from the upper limit frequency to the lower limit frequency. Further, in step ST440, for example, the source frequency f_{S} may be changed in a manner of increasing the value of the frequency from the lower limit frequency to the upper limit frequency. Further, for example, in step ST440, the source frequency f_{S} at the time of plasma ignition may be set as an initial source frequency, and a value farthest from the source frequency f_{S} may be set as a final source frequency, and the source frequency may be changed from the initial source frequency to the final source frequency. After the plasma ignition, the matcher position may be moved from the initial matcher position to the steady matcher position.

Next, the bias signal control ST410 in the source signal supply method MT40 according to the fourth embodiment will be described with reference to FIGS. 15 to 19.

FIG. 15 is a flowchart illustrating an outline of the bias signal control step ST410 according to one embodiment. In the bias signal control according to the embodiment, the bias signal is supplied at the steady bias frequency f_{BC} corresponding to any process recipe (ST450). The steady bias frequency f_{BC} may be a bias frequency of bias signals supplied to steadily maintain the plasma in the process recipe. Further, the bias signal may be pulsed by on/off control or high/low control. Subsequently, the sweep of the source frequency f_{S} is performed at the initial matcher position while supplying the bias signal (ST452). The sweep in step ST452 may be a source frequency sweep at the initial matcher position defined in step ST400.

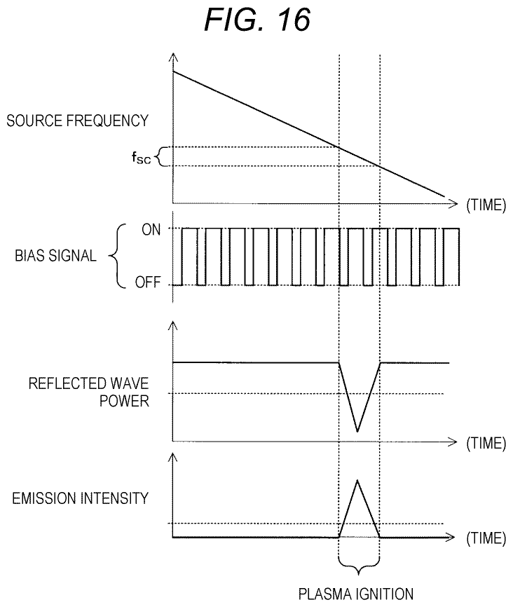

FIG. 16 is a graph illustrating the source frequency, the bias signal, supply wave power, the reflected wave power, and an emission intensity in a case where the bias signal control step ST410 in the example in FIG. 15 is performed. As illustrated in FIG. 16, it can be seen that when the sweep of the source frequency is performed while supplying the pulsed bias signal, the reflected wave power decreases or the emission intensity in the plasma processing space increases at a certain point in time, indicating the plasma ignition.

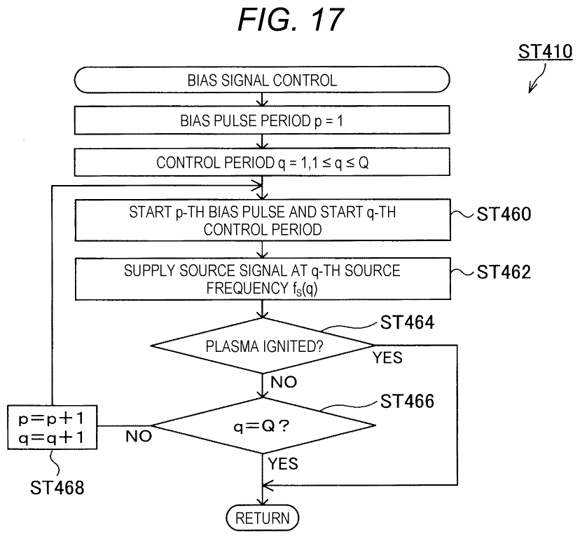

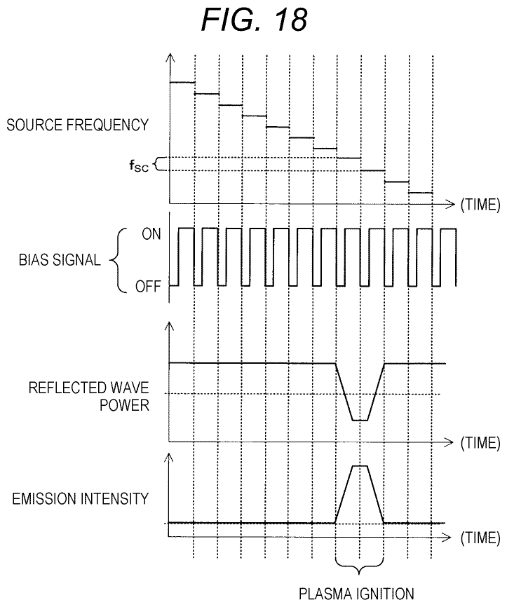

FIG. 17 is a flowchart illustrating an outline of the bias signal control step ST410 according to another embodiment. In the bias signal control according to the other embodiment, a bias period and a control period of the source frequency f_{S} are synchronized with each other. Regarding the bias period, one on/off of a bias rectangular wave shown in FIG. 18 is one period. In the illustrated example, the bias signal is a rectangular wave. Alternatively, the bias signal may be a sine wave. When the bias period p is set to (p=1) and the control period q is set to (q=1), a p-th bias pulse and a q-th control period are started (ST460). Subsequently, the source signal is supplied at a q-th source frequency f_{B}(q) (ST462). Subsequently, it is determined whether the plasma is ignited (ST464). When the plasma is ignited in step ST464, the bias signal control is ended. When the plasma is not ignited in step ST464, it is determined whether the control period q is a maximum value Q (ST466). When the control period q is not the maximum value Q in step ST466, step ST460 and subsequent steps are performed again with the bias pulse period p (p=p+1) and the control period q (q=q+1) (ST468). When the control period q is the maximum value Q in step ST466, the bias signal control is ended. The control period q being the maximum value Q indicates that the freely determined control period q reaches the Q-th control period that is the final control period. For example, when changing the source frequency f_{S} from the upper limit frequency of the steady frequency band to the lower limit frequency, the control period may be set such that the frequency is stepwise decreased for each control period, with the first source frequency f_{S}(1) as the upper limit frequency and the Q-th source frequency f_{S}(Q) as the lower limit frequency. Further, the control period may be set such that the frequency is stepwise increased for each control period, with the first source frequency f_{S}(1) as the lower limit frequency and the Q-th source frequency f_{S}(Q) as the upper limit frequency. Further, the control period may be set such that the frequency is changed from the initial source frequency to the final source frequency f_{S}(Q) for each control period, with the source frequency f_{S} at the time of plasma ignition as the first source frequency f_{S}(1) and a value farthest from the source frequency f_{S} as the Q-th source frequency f_{S}(Q).

FIG. 18 is a graph illustrating the source frequency, the bias signal, the supply wave power, the reflected wave power, and the emission intensity in the case where the bias signal control step ST410 in the example in FIG. 17 is performed. As illustrated in FIG. 18, it can be seen that, by performing control while synchronizing the bias period and the control period of the source frequency, the reflected wave power decreases or the emission intensity in the plasma processing space increases in a certain bias period and control period, indicating the plasma ignition.

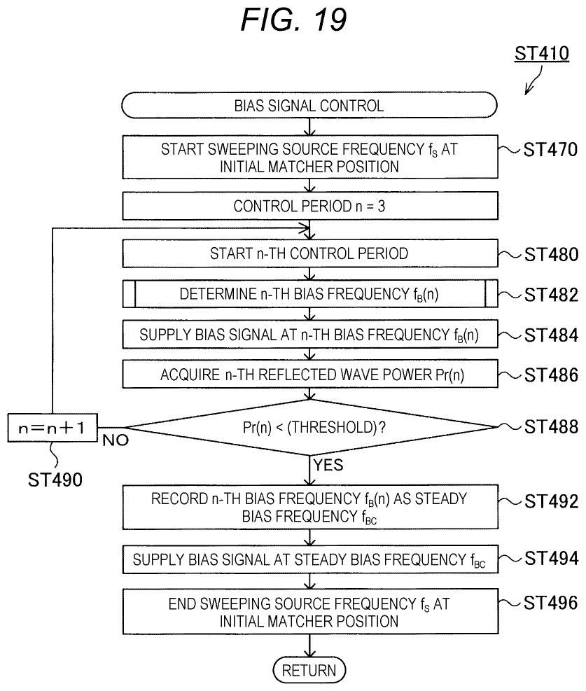

FIG. 19 is a flowchart illustrating an outline of the bias signal control step ST410 according to still another embodiment. In the bias signal control according to the still another embodiment, steps ST480 to ST494 similar to those in the bias signal supply method MT1 are performed. First, a sweep of the source frequency at an initial matcher position is started (ST470). The sweep of the source frequency from the start of the sweep in step ST470 to the end of the sweep in step ST496 to be described later may be the source frequency sweep at the initial matcher position defined in step ST400. In other words, the following steps ST480 to ST494 are performed during the execution of the source frequency sweep at the initial matcher position defined in step ST400. Subsequently, an initial value of the control period n is set to (n=3), and the n-th control period is started (ST480). Subsequently, the n-th bias frequency f_{B}(n) is determined and recorded (ST482). The method of determining the n-th bias frequency f_{B}(n) may be the method defined in step ST102 in the bias signal supply method MT1 described above. Subsequently, a bias signal to which the determined n-th bias frequency f_{B}(n) is applied is supplied (ST484). Subsequently, the n-th reflected wave power Pr(n) reflected from a load when the bias signal is supplied is measured and recorded (ST486). Subsequently, a value of the n-th reflected wave power Pr(n) is compared with a threshold to determine a magnitude relationship thereof (ST488). The threshold may be determined in advance according to a process recipe and recorded, and may be read in step ST488. When the value of the n-th reflected wave power Pr(n) is equal to or greater than the threshold in step ST488, the n-th control period is ended, and the next control period is started with (n=n+1) (ST490). In the (n+1)-th control period, the above-described steps ST480 to ST488 performed in the n-th control period are performed again, and thereafter, the above-described steps ST480 to ST488 are repeated in the same manner in an (n+k)-th control period, with k being any natural number. When the value of the n-th reflected wave power Pr(n) is smaller than the threshold in step ST488, the n-th bias frequency f_{B}(n) is recorded as the steady bias frequency f_{BC} (ST492). Subsequently, the bias signal to which the steady bias frequency f_{BC} is applied is continuously supplied (ST494). Thereafter, the sweep of the source frequency at the initial matcher position is ended (ST496). Although the value of the n-th reflected wave power Pr(n) is compared with the threshold in step ST488, the present disclosure is not limited thereto. Instead of the comparison, for example, a determination as to whether plasma is ignited may be performed. In the case of determining whether plasma is ignited, when it is determined in step ST488 that plasma is not ignited, the n-th control period is ended, and the next control period is started with (n=n+1) (ST490). When it is determined in step ST488 that plasma is ignited, the n-th bias frequency f_{B}(n) is recorded as the steady bias frequency f_{BC} (ST492).

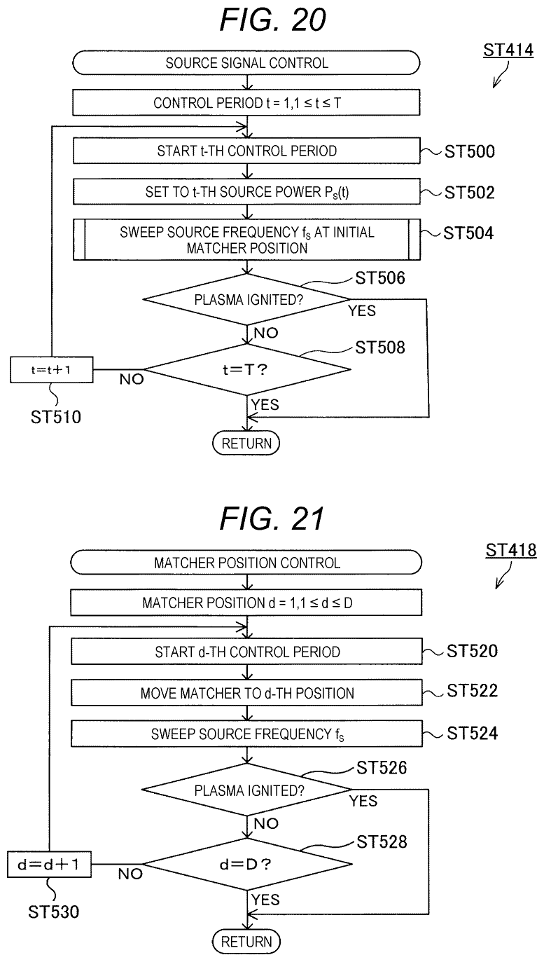

Next, the source signal control ST414 in the source signal supply method MT40 according to the fourth embodiment will be described with reference to FIG. 20.

FIG. 20 is a flowchart illustrating an outline of the source signal control ST414 according to one embodiment. In the source signal control according to the embodiment, the sweep is performed while changing the source power for each control period. First, a control period t is set to (t=1), and the t-th control period is started (ST500). Subsequently, the power of the source signal is set to t-th source power P_{S}(t) (ST502). Subsequently, the sweep of the source frequency at the initial matcher position is performed using the source signal to which the set t-th source power P_{S}(t) is applied (ST504). The sweep in step ST504 may be a source frequency sweep at the initial matcher position defined in step ST400. Subsequently, it is determined whether plasma is ignited (ST506). When plasma is ignited in step ST506, the source signal control is ended. When plasma is not ignited in step ST506, it is determined whether the control period t is a maximum value T (ST508). When the control period t is not the maximum value T in step ST508, step ST500 and subsequent steps are performed again with the control period t (t=t+1) (ST510). When the control period t is the maximum value T in step ST508, the source signal control is ended. The control period t being the maximum value T indicates that the freely determined control period t reaches the T-th control period that is the final control period. For example, the control period may be set such that the source power is stepwise increased for each control period, with freely determined minimum power as first source power P_{S}(1) and freely determined maximum power as T-th source power P_{S}(T).

Next, the matcher position control ST418 in the source signal supply method MT40 according to the fourth embodiment will be described with reference to FIG. 21.

FIG. 21 is a flowchart illustrating an outline of the matcher position control ST418 according to one embodiment. In the matcher position control according to the embodiment, the sweep is performed while changing the matcher position for each control period. First, a control period d is set to (d=1), and a d-th control period is started (ST520). The matcher position before the start of the control is the initial matcher position. Subsequently, the position of the matcher is set to a d-th matcher position P_{S}(d) (ST522). Subsequently, the sweep of the source frequency f_{S} is performed at the set d-th matcher position P_{S}(d) (ST524). Subsequently, it is determined whether plasma is ignited (ST526). When plasma is ignited in step ST526, the matcher position control is ended. When plasma is not ignited in step ST526, it is determined whether the control period d is the maximum value D (ST528). When the control period d is not the maximum value D in step ST528, the control period d is set to (d=d+1) and step ST520 and subsequent steps are performed again (ST530). When the control period d is the maximum value D in step ST528, the matcher position control is ended. The control period d being the maximum value D indicates that the freely determined control period d reaches the D-th control period that is the final control period. For example, the control period may be set such that the matcher is moved stepwise for each control period, with the initial matcher position as a first matcher position P_{S}(1) and the freely determined final position as a D-th matcher position P_{S}(D).

Next, the significance of configuring the source signal supply method MT40 according to the fourth embodiment as described above will be described. In the source signal supply method MT40 according to the fourth embodiment, since the sweep of the source frequency is performed at the initial matcher position close to the ignition matcher position, plasma can be ignited without changing the matcher position requiring a time of the order of seconds. As a result, it is possible to shorten the time until the plasma ignition, and to reduce the damage of the RF power source due to the total sum of the reflected wave power that occur during this time.

When the sweep of the source frequency is performed at the initial matcher position different from the ignition matcher position, there is a problem that matching of the impedance is difficult to be performed, and thus, plasma is unlikely to be ignited. Therefore, the source signal supply method MT40 according to the fourth embodiment includes the bias signal control ST410, the source signal control ST414, and the matcher position control ST418.

With respect to the bias signal control ST410, the control of the bias signal including the change of the bias frequency can be changed in a time of the order of microseconds. In the bias signal control ST410 according to one embodiment, since the steady bias frequency f_{BC} under the plasma ignition condition is supplied, plasma is more easily ignited when the sweep of the source frequency is performed at the initial matcher position. Further, in the bias signal control ST410 according to another embodiment, since the bias period of the bias signal and the control period of the source frequency f_{S} are synchronized, plasma is more easily ignited, and the conditions at the time of plasma ignition are easily obtained. Further, in the bias signal control ST410 according to still another embodiment, since steps ST480 to ST494 similar to those in the bias signal supply method MT1 are performed, the bias frequency can be determined so as to reduce the reflected wave power during the execution of the source frequency sweep at the initial matcher position. As a result, it is possible to reduce the damage to the RF power source due to the total sum of the reflected wave power occurring during the sweep.

With respect to the source signal control ST414, the control of the source signal including the change of the source power can be changed in a time of the order of microseconds.

Therefore, in the source signal supply method MT40 according to the fourth embodiment, the source frequency sweep ST400 at the initial matcher position, the bias signal control ST410, and the source signal control ST414 can be performed in a time of the order of microseconds. Therefore, when plasma is ignited before the source signal control ST414, the time until the plasma ignition can be shortened compared to the method in the related art.

It shall be understood that the embodiments disclosed herein are illustrative and are not restrictive in all aspects. The embodiment described above may be omitted, replaced, or modified in various forms without departing from the scope and spirit of the appended claims.

Reference to an element in the singular is not intended to mean “one and only one” unless explicitly so stated, but rather “one or more.” Moreover, where a phrase similar to “at least one of A, B, or C” is used in the claims, it is intended that the phrase be interpreted to mean that A alone may be present in an embodiment, B alone may be present in an embodiment, C alone may be present in an embodiment, or that any combination of the elements A, B and C may be present in a single embodiment; for example, A and B, A and C, B and C, or A and B and C.

No claim element herein is to be construed under the provisions of 35 U.S.C. 112(f) unless the element is expressly recited using the phrase “means for.” As used herein, the terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus.

The scope of the invention is indicated by the appended claims, rather than the foregoing description.

The following configuration examples are also derived from the present disclosure.

(1) A plasma processing method for performing plasma processing on a substrate, the method including:
setting a matcher position to an initial matcher position;
performing a sweep of a source signal at the initial matcher position;
when plasma is not ignited, performing the sweep while supplying a bias signal;
when plasma is not ignited, performing the sweep by increasing source power; and
when plasma is not ignited, performing the sweep while changing the matcher position.

(2) The plasma processing method according to (1), in which
the initial matcher position is a steady matcher position.

(3) The plasma processing method according to (1) and (2), in which
when supplying the bias signal, the bias signal is supplied with a frequency of the bias signal being changed.

(4) The plasma processing method according to any one of (1) to (3), further including:
acquiring, for each control period of the bias signal, reflected wave power that occurs when the bias signal is supplied; and
determining a frequency f(n) of the bias signal in an n-th control period according to Equation (10) below,

f(n)=f(n−1)−Δf/ΔP×Pr(n−1)×F . . . (10),

Δf=f(n−2)−f(n−1),

ΔP=Pr(n−2)−Pr(n−1),
f(n−2) being a frequency in an (n−2)-th control period, f(n−1) being a frequency in an (n−1)-th control period, Pr(n−2) being the reflected wave power in the (n−2)-th control period, Pr(n−1) being the reflected wave power in the (n−1)-th control period, and n being an integer of 3 or more and F being a constant.

(5) A plasma processing method for performing plasma processing on a substrate, the method including:
acquiring, for each control period of a bias signal, reflected wave power of the bias signal that occurs when the bias signal is supplied to an electrode provided at a substrate support; and
determining a frequency f(n) of the bias signal in an n-th control period according to Equation (11) below,

f(n)=f(n−1)−(Δf/ΔP)/|Δf/ΔP|×|ΔP|×F . . . (11)

Δf=f(n−2)−f(n−1),

ΔP=Pr(n−2)−Pr(n−1),
f(n−2) being a frequency in an (n−2)-th control period, f(n−1) being a frequency in an (n−1)-th control period, Pr(n−2) being the reflected wave power in the (n−2)-th control period, Pr(n−1) being the reflected wave power in the (n−1)-th control period, n being an integer of 3 or more and F being a constant.

1. A plasma processing method for performing plasma processing on a substrate, the method comprising:
acquiring, for each control period of a bias signal, a parameter relating to an impedance matching state when supplying the bias signal to an electrode provided at a substrate support; and
determining a frequency f(n) of the bias signal in an n-th control period according to Equation (1) below,
f(n)=f(n−1)−Δf/ΔP×Pr(n−1)×F . . . (1),
Δf=f(n−2)−f(n−1),
ΔP=Pr(n−2)−Pr(n−1),
f(n−2) being a frequency in an (n−2)-th control period, f(n−1) being a frequency in an (n−1)-th control period, Pr(n−2) being the parameter in the (n−2)-th control period, and Pr(n−1) being the parameter in the (n−1)-th control period, n being an integer of 3 or more, and F being a constant.

2. The plasma processing method according to claim 1, wherein
the parameter is reflected wave power of the bias signal that occurs when the bias signal is supplied to the electrode provided at the substrate support.

3. The plasma processing method according to claim 2, further comprising:
ending the n-th control period and starting a next control period when reflected wave power Pr(n) in the n-th control period is equal to or greater than a threshold, and determining the frequency f(n) of the bias signal again according to Equation (1); and
recording the frequency f(n) of the bias signal in the n-th control period as a steady frequency when the reflected wave power Pr(n) in the n-th control period is smaller than the threshold.

4. A plasma processing method for performing plasma processing on a substrate, the method comprising:
acquiring, for each control period of a pulsed bias signal, a parameter relating to an impedance matching state when supplying the bias signal to an electrode provided at a substrate support; and
determining a frequency f(m, n) of the bias signal in an n-th control period of an m-th pulse according to Equation (2) below,
f(m,n)=f(m−h,n)−Δf/ΔP×Pr(m−h,n)×F . . . (2),
Δf=f(m−h−1,n)−f(m−h,n),
ΔP=Pr(m−h−1,n)−Pr(m−h,n),
f(m−h−1, n) being a frequency in the n-th control period of an (m−h−1)-th pulse, f(m−h, n) being a frequency in the n-th control period of an (m−h)-th pulse, Pr(m−h−1, n) being the parameter in the n-th control period of the (m−h−1)-th pulse, and Pr(m−h, n) being the parameter in the n-th control period of the (m−h)-th pulse, h being an integer of 1 or more, m and n being integers of 3 or more, and F being a constant.

5. The plasma processing method according to claim 4, wherein
the parameter is reflected wave power of the bias signal that occurs when the bias signal is supplied to the electrode provided at the substrate support.

6. The plasma processing method according to claim 5, further comprising:
ending an (m, n)-th control period and starting a next control period when reflected wave power Pr(m, n) in the (m, n)-th control period is equal to or greater than a threshold, and determining again the frequency f(m, n) of the bias signal according to Equation (2); and
recording the frequency f(m, n) of the bias signal in the (m, n)-th control period as a steady frequency when the reflected wave power Pr(m, n) in the (m, n)-th control period is smaller than the threshold.

7. A plasma processing method for performing plasma processing on a substrate, the method comprising:
acquiring, for each control period of a pulsed bias signal, a parameter relating to an impedance matching state when supplying the bias signal to an electrode provided at a substrate support;
in first loop control, determining a frequency f(m, n) of the bias signal in an (m, n)-th control period according to Equation (3) below,
when a parameter Pr(m, n) in an n-th control period of an (m, n)-th pulse is equal to or greater than a reference value, ending the n-th control period and starting a next control period, and determining again the frequency f(m, n) of the bias signal according to Equation (3), and
when the parameter Pr(m, n) in the n-th control period of the (m, n)-th pulse is smaller than the reference value or when n reaches a specified number, ending the first loop control and starting second loop control; and
in the second loop control, determining the frequency f(m, n) of the bias signal according to Equation (4),
when the parameter Pr(m, n) of the (m, n)-th control period is equal to or greater than a threshold, ending the n-th control period and starting a next control period, and determining again the frequency f(m, n) of the bias signal according to Equation (4), and
when the parameter Pr(m, n) in the (m, n)-th control period is smaller than the threshold or when n reaches a specified number, recording the frequency f(m, n) of the bias signal in the (m, n)-th control period as a steady frequency,
f(m,n)=f(m−1,n)−Δf₁/ΔP₁×Pr(m−1,n)×F . . . (3),
f(m,n)=f(m,n−1)−Δf₂/ΔP₂×Pr(m,n−1)×F . . . (4),
Δf₁=f(m−2,n)−f(m−1,n),
ΔP₁=Pr(m−2,n)−Pr(m−1,n),
Δf₂=f(m,n−2)−f(m,n−1),
ΔP₂=Pr(m,n−2)−Pr(m,n−1),
f(m−2, n) being a frequency in the n-th control period of an (m−2)-th pulse, f(m−1, n) being a frequency in the n-th control period of an (m−1)-th pulse, Pr(m−2, n) being the parameter in the n-th control period of the (m−2)-th pulse, Pr(m−1, n) being the parameter in the n-th control period of the (m−1)-th pulse, f(m, n−2) being a frequency in an (n−2)-th control period of the m-th pulse, f(m, n−1) being a frequency in an (n−1)-th control period of the m-th pulse, Pr(m, n−2) being a parameter power in the (n−2)-th control period of the m-th pulse, Pr(m, n−1) being the parameter of the (n−1)-th control period of the m-th pulse, m and n being integers of 3 or more, and F being a constant.

8. The plasma processing method according to claim 7, wherein
the parameter is reflected wave power of the bias signal that occurs when the bias signal is supplied to the electrode provided at the substrate support.

9. The plasma processing method according to claim 1, further comprising:
setting a matcher position to an initial matcher position;
performing a sweep of a source signal at the initial matcher position;
when plasma is not ignited, performing the sweep while supplying the bias signal;
when plasma is not ignited, performing the sweep by increasing source power; and
when plasma is not ignited, performing the sweep while changing the matcher position.

10. The plasma processing method according to claim 9, wherein
when supplying the bias signal, the bias signal is supplied with a frequency of the bias signal being changed.

11. The plasma processing method according to claim 8, further comprising:
acquiring, for each control period of the bias signal, the reflected wave power that occurs when the bias signal is supplied; and
determining the frequency f(n) of the bias signal in the n-th control period according to Equation (5) below,
f(n)=f(n−1)−Δf/ΔP×Pr(n−1)×F . . . (5),
Δf=f(n−2)−f(n−1),
ΔP=Pr(n−2)−Pr(n−1),
f(n−2) being a frequency in the (n−2)-th control period, f(n−1) being a frequency in the (n−1)-th control period, Pr(n−2) being the reflected wave power in the (n−2)-th control period, Pr(n−1) being the reflected wave power in the (n−1)-th control period, n being an integer of 3 or more, and F being a constant.

12. A plasma processing apparatus for performing plasma processing on a substrate, the plasma processing apparatus comprising:
a substrate support;
an RF power source configured to supply a bias signal to an electrode provided at the substrate support, and controllably change a frequency of the bias signal;
a reflected wave detector configured to acquire reflected wave power that occurs when the bias signal is supplied to the electrode; and
controller circuitry, wherein
the controller circuitry is configured to acquire, for each control period of the bias signal, the reflected wave power of the bias signal that occurs when the bias signal is supplied to the electrode provided at the substrate support, and determine a frequency f(n) of the bias signal in an n-th control period according to Equation (6) below,
f(n)=f(n−1)−Δf/ΔP×Pr(n−1)×F . . . (6),
Δf=f(n−2)−f(n−1),
ΔP=Pr(n−2)−Pr(n−1),
f(n−2) being a frequency in an (n−2)-th control period, f(n−1) being a frequency in the an (n−1)-th control period, Pr(n−2) being the reflected wave power in the (n−2)-th control period, Pr(n−1) being the reflected wave power in the (n−1)-th control period, n being an integer of 3 or more, and F being a constant.

13. The plasma processing method according to claim 2, further comprising:
setting a matcher position to an initial matcher position;
performing a sweep of a source signal at the initial matcher position;
when plasma is not ignited, performing the sweep while supplying the bias signal;
when plasma is not ignited, performing the sweep by increasing source power; and
when plasma is not ignited, performing the sweep while changing the matcher position.

14. The plasma processing method according to claim 3, further comprising:
setting a matcher position to an initial matcher position;
performing a sweep of a source signal at the initial matcher position;
when plasma is not ignited, performing the sweep while supplying the bias signal;
when plasma is not ignited, performing the sweep by increasing source power; and
when plasma is not ignited, performing the sweep while changing the matcher position.

15. The plasma processing method according to claim 4, further comprising:
setting a matcher position to an initial matcher position;
performing a sweep of a source signal at the initial matcher position;
when plasma is not ignited, performing the sweep while supplying the bias signal;
when plasma is not ignited, performing the sweep by increasing source power; and
when plasma is not ignited, performing the sweep while changing the matcher position.

16. The plasma processing method according to claim 7, further comprising:
setting a matcher position to an initial matcher position;
performing a sweep of a source signal at the initial matcher position;
when plasma is not ignited, performing the sweep while supplying the bias signal;
when plasma is not ignited, performing the sweep by increasing source power; and
when plasma is not ignited, performing the sweep while changing the matcher position.

17. The plasma processing method according to claim 2, further comprising:
ending the n-th control period and starting a next control period when the reflected wave power Pr(n) in the n-th control period is equal to or greater than a threshold, and determining the frequency f(n) of the bias signal again according to Equation (1).

18. The plasma processing method according to claim 5, further comprising:
ending an (m, n)-th control period and starting a next control period when the reflected wave power Pr(m, n) in the (m, n)-th control period is equal to or greater than a threshold, and determining again the frequency f(m, n) of the bias signal according to Equation (2).

19. The plasma processing method according to claim 8, further comprising:
acquiring, for each control period of the bias signal, the reflected wave power that occurs when the bias signal is supplied.
